(19) United States
(12) Patent Application Publication
(10) Pub. No.: US 2025/0052925 A1
(43) Pub. Date: Feb. 13, 2025

(54) Frequency-Selective Optical Metalens Filters

(71) Applicant: Imagia, Inc., Las Vegas, NV (US)

(72) Inventors: Gregory Kress, Las Vegas, NV (US); Abdoulaye Ndao, Brookline, MA (US)

(21) Appl. No.: 18/928,013

(22) Filed: Oct. 26, 2024

Related U.S. Application Data
(62) Division of application No. 17/352,911, filed on Jun. 21, 2021.
(60) Provisional application No. 63/120,546, filed on Dec. 2, 2020.
(60) Provisional application No. 63/046,094, filed on Jun. 30, 2020.

(51) Int. Cl. G02B 1/00; G02B 5/28; H01L 27/15; H01L 33/58

(52) U.S. Cl. CPC G02B 1/002; G02B 5/28; H01L 27/156; H01L 33/58; G02B 2207/101

(57) ABSTRACT

Various embodiments of optical metalens and electronic displays using metalenses are described herein. In some embodiments, a metalens includes an array of passive deflector elements with varying diameters that extend from a substrate with a repeating pattern of deflector element diameters. Interelement on-center spacings of the passive deflector elements may be selected as a function of an operational wavelength of the optical metalens. Each passive deflector element has a height and a width that are each less than a smallest wavelength within the operational bandwidth. An electronic display may include a multi-pixel light-emitting diode (LED) display, such as an RGB LED display. A metalens comprising a plurality of metalens subpixels may deflect the optical radiation from each corresponding LED subpixel at a target deflection angle. Each metalens subpixel may include a two-dimensional array of passive deflector elements in a repeating pattern of deflector element diameters.

### RELATED APPLICATIONS

This application is divisional application of U.S. patent application Ser. No. 17/352,911 filed on Jun. 21, 2021 titled “Optical Metalenses,” which claims benefit of and priority to U.S. Provisional Patent Application No. 63/120,546 filed on Dec. 2, 2020 titled “Metalenses for Optical Displays” and U.S. Provisional Patent Application No. 63/046,094 filed on Jun. 30, 2020 also titled “Metalenses for Optical Displays,” each of which is hereby incorporated by reference in its entirety.

### TECHNICAL FIELD

This disclosure relates to metamaterial lenses to control deflection in transmissive and reflective structures. Additionally, this disclosure relates to electronic displays including red, green, and blue (RGB) electronic displays.

### BRIEF DESCRIPTION OF THE DRAWINGS

FIGS. 1A-1C illustrate examples of optical paths through concave, convex, and flat plate optical lenses, according to various embodiments.

FIG. 2A illustrates a top-down view of an example representation of a pattern of deflector elements for a metalens structure, according to one embodiment.

FIG. 2B illustrates an enlarged perspective view of the example representation of the pattern of deflector elements in the metalens of FIG. 2A, according to one embodiment.

FIG. 3A illustrates an example block diagram of a side view of a metalens with nanopillar deflectors positioned on a substrate, according to one embodiment.

FIG. 3B illustrates the example block diagram of the metalens of FIG. 3A operating to reflect incident optical radiation, according to one embodiment.

FIG. 3C illustrates the example block diagram of the metalens of FIG. 3A transmissively steering incident optical radiation, according to one embodiment.

FIGS. 4A-4B illustrate metalenses used in conjunction with laser-scanning subsystems, according to various embodiments.

FIG. 5A illustrates an example system with a metalens and waveguide used in conjunction with a laser scanning subsystem, according to one embodiment.

FIG. 5B illustrates an example display system that utilizes input and output metalenses in conjunction with a waveguide, according to one embodiment.

FIG. 6A illustrates an example of a unit cell of a metalens with a cylindrical deflector element for use with a red laser, according to one embodiment.

FIG. 6B illustrates phase shift values for various diameters of a cylindrical deflector element in a unit cell of a metalens illuminated by a red laser, according to one embodiment.

FIG. 6C illustrates another example of a unit cell of a metalens with a cylindrical deflector element with a cylindrical cavity formed therein, according to one embodiment.

FIG. 6D illustrates a side cutaway view of the example unit cell of FIG. 6C, according to one embodiment.

FIG. 7A illustrates an example of a display system that includes a metalens with rectangular deflector elements, an array of light-emitting diodes (LED array), and a polarizer to form a light-field, according to one embodiment.

FIG. 7B illustrates an example of a display system that includes a metalens with rectangular deflector elements, an LED array, and a polarizer to subdivide optical radiation from each pixel of the LED array into two different directions for pupil replication, according to one embodiment.

FIG. 8A illustrates an example of a display system that includes a metalens with deflector elements operating in a waveguide mode and an LED array without a polarizer, according to one embodiment.

FIG. 8B illustrates another example of a display system that includes a metalens with deflector elements operating in the waveguide mode and an LED array without a polarizer, according to one embodiment.

FIG. 9 illustrates a portion of an example LED display and various levels of detail of a tuned metalens with RGB (red, green, blue) subpixels, according to one embodiment.

FIG. 10A illustrates an example unit cell of a red metalens subpixel, according to one embodiment.

FIG. 10B illustrates transmission values for various diameters of a cylindrical deflector element in a unit cell for the example red metalens subpixel of FIG. 10A, according to one embodiment.

FIG. 10C illustrates phase shift values for various diameters of a cylindrical deflector element in a unit cell for the example red metalens subpixel of FIG. 10A, according to one embodiment.

FIG. 11A illustrates an example unit cell of a green metalens subpixel, according to one embodiment.

FIG. 11B illustrates transmission values for various diameters of a cylindrical deflector element in a unit cell for the example green metalens subpixel of FIG. 11A, according to one embodiment.

FIG. 11C illustrates phase shift values for various diameters of a cylindrical deflector element in a unit cell for the example green metalens subpixel of FIG. 11A, according to one embodiment.

FIG. 12A illustrates an example unit cell of a blue metalens subpixel, according to one embodiment.

FIG. 12B illustrates transmission values for various diameters of a cylindrical deflector element in a unit cell for the example blue metalens subpixel of FIG. 12A, according to one embodiment.

FIG. 12C illustrates phase shift values for various diameters of a cylindrical deflector element in a unit cell for the example blue metalens subpixel of FIG. 12A, according to one embodiment.

FIG. 13A illustrates an example of a sub-unit-cell deflector element with a dual-frequency response, according to one embodiment.

FIG. 13B illustrates an example multicell deflector unit cell with dual-frequency responses, according to one embodiment.

FIG. 14A illustrates an example of a sub-unit-cell deflector element for an RGB display, according to one embodiment.

FIG. 14B illustrates an example multicell deflector unit cell for R, G, and B, frequency responses, according to one embodiment.

FIG. 15A illustrates an example of a transmissive metalens filter to focus a narrow band of optical radiation, according to one embodiment.

FIG. 15B illustrates a graph of the normalized power of the filtered and focused optical radiation with respect to wavelength, according to one embodiment.

FIG. 16A illustrates a reflective metalens filter to focus a narrow band of optical radiation, according to one embodiment.

FIG. 16B illustrates a graph of the normalized power of the filtered and focused optical radiation with respect to wavelength, according to one embodiment.

FIG. 17A illustrates a unit cell of an example narrowband frequency-selective filter, according to one embodiment.

FIG. 17B illustrates a graph of the magnitude relative to radius selection of the array of passive deflector elements, according to one embodiment.

FIG. 17C illustrates a graph of the phase shift relative to the various radius selections of the array of passive deflector elements, according to one embodiment.

FIG. 17D illustrates an example block diagram of an array of passive deflector elements for use in a unit cell of a frequency-selective filter, according to one embodiment.

FIGS. 18A-18F illustrate an example process for fabricating a metalens with an array of passive deflector elements having varying diameters that extend from a substrate, according to one embodiment.

FIGS. 19A-19D illustrate another example process for fabricating a metalens with an array of passive deflector elements having varying diameters that extend from a substrate, according to one embodiment.

FIG. 20A illustrates a subpixel of a complementary metal oxide semiconductor (CMOS) digital imaging sensor with a microlens and color filter, according to one embodiment.

FIG. 20B illustrates a subpixel of a digital imaging sensor using a metalens to filter and refract the optical radiation, according to one embodiment.

### DETAILED DESCRIPTION

Various embodiments, systems, apparatuses, and methods are described herein that relate to the controlled deflection of incident optical radiation. Examples are described herein for reflective optical systems that reflect incident optical radiation. Examples are also described herein for optically transmissive optical systems that refract, deflect, or otherwise modify optical radiation passing therethrough. In some examples, electronic displays, such as RGB LED displays, include variations of the metalenses described herein. Additionally, the presently described metalenses can be used in combination with waveguides for optical transmission and/or near eye displays (NEDs), such as head mounted displays (HMD) and wearable displays. An input coupler may be formed using a variation of the metalenses described herein to couple an image source to a waveguide. The waveguide may convey the optical radiation forming the images to an output coupler that includes another metalens according to one of the embodiments described herein.

The output coupling metalens may deflect and focus the optical radiation (e.g., based on frequency and/or with a frequency selective filter) to form an image visible to one eye of a user. In some embodiments, the output coupling metalens may be used to deflect and focus the optical radiation as a stereo image or as a duplicated image on both eyes of the user or even on the eyes of multiple users.

According to various embodiments, an electronic display may include a multi-pixel light-emitting diode (LED) display layer to generate optical radiation at various wavelengths (e.g., different visible colors of light) using at least three different colors of LED subpixels (e.g., red, green, and blue subpixels for an RGB display). A metalens layer may include a plurality of metalens subpixels. Each metalens subpixel may correspond to one of the LED subpixels. In some embodiments, a multi-frequency metalens subpixel may be responsive to multiple frequencies allowing a single multi-frequency metalens subpixel to be used for each pixel of the RGB display.

The metalens subpixels deflect the optical radiation from each corresponding LED subpixel at a target deflection angle for focusing, image replication, color separation, and/or other deflection purposes. Each metalens subpixel comprises an array (e.g., a two-dimensional array for two-dimensional LED subpixels) of passive deflector elements with varying diameters. The passive deflector elements extend from a substrate (e.g., normal to, substantially normal to, or at an angle with respect to the substrate). The passive deflector elements are arranged in a repeating pattern of deflector element diameters with constant and/or frequency-dependent interelement on-center spacings.

Various embodiments of the metalenses described herein may be used in combination with an imaging sensor, such as a charge-coupled device (CCD) or complementary metal oxide semiconductor (CMOS) sensor array. For example, various embodiments of the metalenses described herein may be utilized in place of frequency masks, filters, microlenses, and other optical elements of CCD and CMOS digital image sensors. Frequency selective metalenses can be tuned (i.e., configured with specific deflector element dimensions and patterns) to filter and/or deflect (e.g., refract or reflect) optical radiation received by each pixel or subpixel in a digital imaging sensor.

The repeating pattern of deflector element diameters may include passive deflector elements having any number of different diameters. Some of the illustrated examples include passive deflector elements with six different diameters arranged in a repeating pattern with constant on-center spacing. In other embodiments, the number of passive deflector elements with different diameters may be fewer than six or more than six (e.g., 8, 10, or even dozens of different diameters). In some embodiments, the height to which each passive deflector element extends from the substrate in a given metalens subpixel is constant. In fact, in some embodiments, the height to which each passive deflector element extends from the substrate may be constant for all the metalens subpixels, regardless of the operational frequency thereof. Thus, while the repeating pattern of diameters of deflector elements may vary based on the operational frequency, the heights of the deflector elements may all be the same.

As described herein, the passive deflector elements may be polarization-independent or polarization-dependent. For a given frequency, the polarization-dependent passive deflector elements may extend from the substrate to a shorter height than the polarization-independent passive deflector elements, while the pattern of deflector element diameters may remain substantially the same.

Accordingly, polarization-independent passive deflector elements may have a height-to-diameter (height: diameter) aspect ratio that is greater than 1. That is, the height of each polarization-independent passive deflector element is generally greater than the diameter thereof. In contrast, polarization-dependent passive deflector elements may have a height: diameter aspect ratio that is less than 1. That is, the height of each polarization-dependent passive deflector element may generally be less than the diameter thereof.

Metalens embodiments utilizing polarization-dependent passive deflector elements may also include a polarizing filter to polarize the optical radiation before it is deflected by the deflector elements. For example, a polarizing layer may be positioned on the substrate between the substrate and the polarization-dependent passive deflector elements. In such embodiments, the polarization-dependent passive deflector elements may extend from the substrate through the polarizing layer or extend from the polarizing layer on the substrate. In some embodiments, the substrate and the polarizing layer may be combined or described in combination as a polarizing substrate.

The exact shape and size of the deflector elements may depend on the manufacturing process utilized and target operational characteristics. In many embodiments, including the illustrated embodiments, the deflector elements are substantially cylindrical and extend normal to (e.g., perpendicular to) the plane of the underlying substrate. The cylindrical deflector elements can be described as having a diameter (D), a height (H), and an on-center nearest neighbor interelement spacing (P). A metalens subpixel may include many unit cells, where each unit cell includes a cylindrical deflector element extending from a substrate. A metalens subpixel may be formed by combining many unit cells in a two-dimensional array with varying diameters of cylindrical deflector elements (e.g., in a repeating pattern of deflector element diameters).

In some embodiments, the cylindrical deflector elements include a cavity or depression formed therein. The cavity may be cylindrical and only extend partially into the cylindrical deflector elements. For example, the depth of the cavity may be half the height of the cylindrical deflector elements, less than half the height of the cylindrical deflector elements, or more than half the height of the cylindrical deflector elements. In some embodiments, the cavity may be filled with air or another material that has a different electromagnetic permittivity than the deflector element.

While many of the metalenses described herein are described in the context of an electronic display, metalenses may be used for other purposes and applications. In various embodiments, a metalens includes an array of passive deflector elements with varying diameters that extend from a substrate with a repeating pattern of deflector element diameters. The interelement on-center spacings of the passive deflector elements may be selected as a function of an operational wavelength of the optical metalens. Each passive deflector element has a height and a width that are each less than a smallest wavelength within the operational bandwidth.

The repeating pattern of deflector element diameters within the optical metalens includes passive deflector elements having at least six different diameters. Again, the passive deflector elements may be polarization-independent in some embodiments. When used in combination with a polarizer or polarizing layer, the passive deflector elements may be polarization-dependent.

In one specific embodiment, an optical metalens configured to deflect a wavelength of red light includes a repeating pattern of deflector element diameters ranging from 80 nanometers to 220 nanometers. The exact heights and spacing may vary based on the wavelength, target deflection response, and manufacturing processes. However, in one specific embodiment the height of the deflector elements is 280 nanometers with nearest neighbor interelement spacing of approximately 230 nanometers. In another specific embodiment, the height of the deflector elements is 220 nanometers with nearest neighbor interelement spacings of approximately 250 nanometers.

Again, while the specific dimensions and spacing characteristics may vary based on the wavelength, target deflection response, and/or manufacturing processes, specific examples are provided herein to facilitate a complete understanding of the systems, methods, and apparatuses described herein. In one embodiment, the optical metalens is configured to deflect a wavelength of green light and has a repeating pattern of passive polarization-independent deflector elements with diameters ranging from 80 nanometers to 150 nanometers. In one embodiment, the optical metalens is configured to deflect a wavelength of blue light and has a repeating pattern of passive polarization-independent deflector elements with diameters ranging from 40 nanometers to 140 nanometers, or a narrower range in some embodiments (e.g., 80 to 140 nanometers). In one specific embodiment, an optical metalens for a wavelength of blue light has a repeating pattern of deflector elements with diameters ranging from 80 nanometers to 140 nanometers.

In some embodiments, each metalens or metalens subpixel includes a plurality of unit cells arranged in a one-dimensional or two-dimensional array. In some embodiments, each unit cell may include a single deflector element and the array of deflector elements may be configured for a single frequency response (or narrowband frequency response). In other embodiments, each unit cell may include multiple deflector elements such that the array of deflector elements provides a multi-frequency response.

In another embodiment, a metalens is used within a transmissive medium to form a frequency selective optical filter. For example, the frequency selective optical filter may be conceptually described as a two-dimensional array of subwavelength unit cells, where each unit cell includes an optically transmissive medium and an array of passive deflector elements with varying diameters arranged therein. The interelement on-center spacings of the passive deflector elements can be selected to reflect optical radiation within a target bandwidth to a focal point. Optical radiation outside of the target bandwidth (e.g., a narrow bandwidth of optical radiation of 10-100 nanometers) is deflected or passed through the optically transmissive medium.

An understanding of traditional optical lenses may be helpful to understand the possible applications and functions of various embodiments and applications of the metalenses described herein. Traditional optical lenses and mirrors (e.g., glass or acrylic lenses) are formed with a curvature to modify the optical path of incident optical radiation. Multiple lenses and/or mirrors may be combined with various indices of refraction, curvatures, coatings, and other features to achieve specific optical goals.

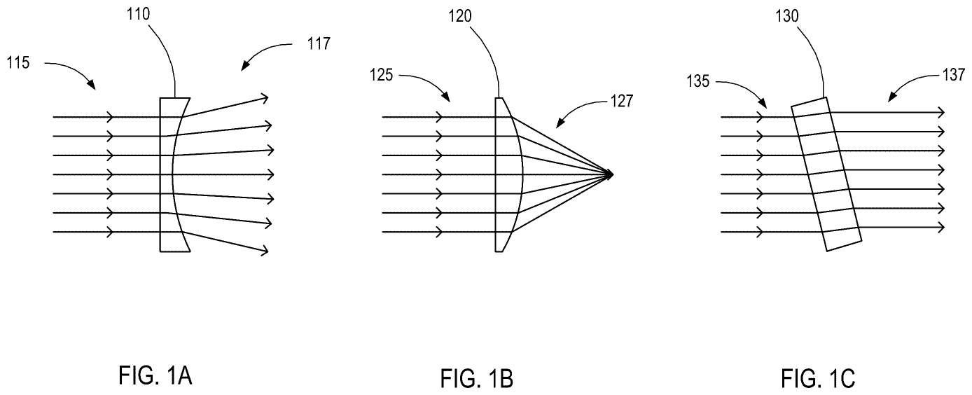

FIGS. 1A-1C illustrate examples of optical paths through concave, convex, and flat plate optical lenses 110, 120, and 130. Specifically, FIG. 1A illustrates an example of a concave lens 110 that receives incident optical radiation 115 and causes it to diverge as divergent optical radiation 117. FIG. 1B illustrates incident optical radiation 125 that converges as converging optical radiation 127 as it passes through the convex lens 120.

FIG. 1C illustrates an incident optical radiation 135 incident at an angle relative to a planar surface of a flat plate optical lens 130. The output optical radiation 137 is shifted as it passes through the flat plate optical lens 130. The degree or amount of phase shift is based on the difference between the refractive index of the surrounding media (e.g., air, water, waveguide, etc.) and the refractive index of the flat plate optical lens 130. Convex, concave, and other shapes of mirrors can be used to achieve other manipulations of incident optical radiation.

Metamaterial-based lenses and mirrors may be formed as relatively thin (e.g., <1 mm) elements that provide controlled deflection without curved surfaces. As described herein, a substrate surface may be configured as a transmissive surface to allow optical radiation to pass therethrough, or as a reflective surface to reflect optical radiation therefrom. Subwavelength-scale features may be patterned on a surface of the substrate to deflect incident optical radiation in a controlled manner to obtain a target optical radiation output at any angle between 0° to 180°. Such a device is referred to herein as a metalens. Various embodiments and variations of metalenses are described herein. Metalenses are broadly defined herein to encompass both transmissive and reflective devices.

In some embodiments, subwavelength-scale features may be formed on more than one surface of the substrate. For example, subwavelength-scale features may be formed on a receiving side of a transmissive substrate and an output side of the transmissive substrate. A metalens may be used to deflect optical radiation within free space (e.g., air) or to couple optical radiation between free space and another transmissive medium, such as a waveguide, traditional optical lenses, a fiber optic transmission line, or the like.

In various embodiments, a surface (or multiple surfaces) of the substrate is patterned with an array of deflector elements. According to various embodiments calculated, estimated, modeled, or optimized to achieve specific target deflection patterns, the array of deflector elements may be uniformly spaced, periodically spaced, aperiodically spaced, and/or arranged in repeating patterns of the same.

Each deflector element in the array of deflector elements may have subwavelength dimensions, such that the deflector element array collectively exhibits metamaterial behaviors for a relatively narrow band of optical radiation (e.g., a target operational bandwidth). In some embodiments, the deflector elements may extend substantially orthogonal to the planar surface of the substrate. In applications in which the metalens is used in combination with an RGB LED display, the fall off or cutoff frequency of the narrowband response may not be as critical since the frequencies of the red, green, and blue light are relatively far apart on the frequency spectrum.

The contact surface of a deflector element contacting the substrate may be a circle, oval, square, rectangle, an n-sided polygon, or another shape. The deflector element may extend from the planar surface to a height that is greater than a length or width dimension of the deflector element. For example, each of the deflector elements may have a circular contact surface with a diameter less than the smallest wavelength within the operational bandwidth and extend from the substrate as a pillar to a height, H. In various embodiments, the height, H, may also be less than the smallest wavelength within the operational bandwidth. The deflector elements may be described as subwavelength, as having subwavelength features, as having subwavelength dimensions, and/or as having subwavelength interelement spacings.

In some embodiments, each deflector element may be a non-circular pillar extending from a substrate or positioned within a substrate (e.g., as illustrated and described herein in the context of a frequency-selective filter). For example, each deflector element may have a square, rectangular, oval, hexagonal, or other shape profile and extend from the substrate to a predetermined height. In some embodiments, each of the deflector elements in a deflector element array may extend to the same height. In other embodiments, the heights of various deflector elements may vary randomly, form a slope relative to the planar surface of the substrate, and/or conform to a repeating pattern.

In some embodiments, each deflector element may be a pillar or nanopillar (e.g., a circular or non-circular pillar) formed from titanium dioxide, polycrystalline silicon (poly-Si), and/or silicon nitride that extends from, for example, a silicon dioxide substrate or magnesium fluoride substrate. Such pillars, including both circular and non-circular variations, may be referred to as nanopillars due to their subwavelength characteristics and nanometer dimensions. In some embodiments, the substrate may comprise multiple layers of substrates with different refractive indices and/or comprise different combinations of materials. For example, in some embodiments, the substrate may comprise a Bragg reflector formed as a sequence of layers of two or more different optical materials having different refractive indices. In various embodiments, the deflector elements are passive subwavelength deflectors that are polarization independent.

The deflection pattern generated by the metalens may be influenced or controlled by careful selection of pillar height, diameter, spacing, and pattern arrangement on the substrate. Metalenses may have a deflector element array configured to generate a converging deflection pattern, a diverging deflection pattern, or another target deflection pattern to achieve a specific deflection goal.

In some embodiments, a metalens includes an array of passive, polarization-independent deflector elements extending from a transmissive substrate. The metalens may be incorporated as part of a laser-based scanning illumination engine to output collimated optical radiation along one dimension of an output surface of the metalens in response to received optical radiation incident at varying angles of incidence on a corresponding dimension of a receiving surface of the metalens (e.g., a “receive surface” of a metalens).

In another embodiment, the angle of output optical radiation may vary based on the location on the output surface of the metalens. The spatially varied output angles of deflected optical radiation may be configured to form multiple depth planes, pupil replication, or expansion of a viewing “eyebox.”

In some embodiments, a single metalens may be responsive to multiple colors of optical radiation sufficient for combination in full-color optical displays. Multiple different functionalities may be combined within a single lens to respond to different states of polarization (e.g., for spatial-multiplexing or time-multiplexing). In other embodiments, multiple metalenses may be stacked, spatially multiplexed, time-multiplexed, or otherwise arranged for use in full-color optical displays. For example, three different metalenses may be stacked for use in an RGB optical display.

The stacked metalenses may include a first metalens configured with an array of deflector elements with dimensions to deflect red optical radiation, a second metalens configured with an array of deflector elements with dimensions to deflect green optical radiation, and a third metalens configured with an array of deflector elements with dimensions to deflect blue optical radiation. In some embodiments, a metalens may be used in place of injection optics for a laser-based scanning illumination engine or LED microdisplay coupled to a waveguide. The metalens may be used to efficiently deflect incident optical radiation from a laser source into a waveguide for total internal reflection.

Variations of the systems and methods described herein may be used or adapted for use in near-to-eye (NTE) displays, such as NTE displays used in wearable technology, smart glasses, augmented reality headsets, virtual reality headsets, heads-up displays, and the like. For example, a metalens may be used as part of an NTE display to collimate optical radiation into parallel rays for delivery to the eye of the user at “infinite focus.” Similarly, a metalens may be used as part of an NTE display to deliver optical radiation to the eye of the user at target angles that vary spatially along the surface of the metalens to cause an image to appear to originate from a target focal depth plane.

In other embodiments, a metalens may be used as part of an NTE display to duplicate source images and cause the duplicated source images to appear as if they originate from different positions in the visual field, for example, to facilitate pupil replication or expansion of the effective “eyebox” of the NTE display. The metalens may be used to expand the source image of an NTE display to have a wider range of divergence angles (e.g., act as a diffuser) to provide a wider effective field of view.

Variations of the systems and methods described herein may be used or adapted for use in light-field displays. As used herein, the term “light-field display” is used to describe any of a wide variety of displays using various technologies to render a three-dimensional image field to one or more users without the use of polarized or active-shutter glasses. Light-field displays deliver an image to each eye of the user at slightly different perspectives to provide binocular disparity for depth perception. The different images transmitted to the eyes of the user cause the user to perceive the image as a three-dimensional image. As an example, a lenticular lens overlaid on a digital display may be used to deliver different images to each eye of the user. Three-dimensional displays using lenticular lens technology have fundamentally limited fields of view.

The presently described systems and methods relating to metalenses can be used to create advanced light-field displays that can be viewed from different perspectives simultaneously by multiple users. Similarly, metalenses can be used to create advanced light-field displays that deliver an image from different perspectives as a single user moves through the visual field. The metalenses may deliver variations of an image to different spatial locations within the visual field to provide the user with a natural-appearing three-dimensional image that accounts for motion, parallax, occlusion, and/or accommodation.

Some three-dimensional displays use a two-dimensional array of microlenses (e.g., a microlens array or “MLA”) with lenslets that span multiple pixels of the underlying electronic display. In such embodiments, the microlenses cause the user to perceive only one of the underlying pixels based on the position of the user's eye relative to each respective lenslet. The metalens-based approaches described herein avoid undesirable field-of-view, reduced fill factor, and other optical deficiencies fundamentally associated with microlens solutions. Specifically, three-dimensional displays utilizing metalenses to deliver different images (e.g., different perspectives of an image) to different locations within the visual field provide an improved optical performance, a finer pitch, and a lower-profile than comparable microlens-based solutions.

According to various embodiments, the metalenses described herein may be fabricated using any of a wide variety of suitable manufacturing techniques, including without limitation nanoimprinting manufacturing techniques, CMOS fabrication techniques, and/or ultraviolet lithography processes. Relatively low aspect ratios (e.g., the ratio of the height to the width of each nanopillar deflector element) allow for relatively faster, cheaper, and higher fidelity manufacturing than competing technologies. For example, the array of nanopillar deflector elements and the underlying substrate may use resonant modes that are electromagnetically coupled to form a metalens that is ultrathin (e.g., less than one wavelength). In some of the specific embodiments described herein, metalenses have been demonstrated to have transmission efficiencies in excess of 85% using devices having a thicknesses of less than one-half (½) of the operational wavelength.

In various embodiments, an array of polarization-independent, passive deflector elements patterned on a transmissive or reflective substrate may be adapted to deflect a relatively narrow band of coherent optical radiation (e.g., from a laser light source) in a prescribed direction, arbitrarily based on the origin of the optical radiation (e.g., pixel-by-pixel variation), and/or collimated to provide an effective “infinite focus.”

In other embodiments, an array of polarization-dependent, passive deflector elements may be patterned on a transmissive or reflective substrate for use with a relatively wide band of noncoherent optical radiation (e.g., from an LED light source) in a prescribed direction, arbitrarily based on the origin of the optical radiation (e.g., pixel-by-pixel variation), and/or collimated to provide an effective “infinite focus.”

As described herein, an array of nanopillar deflector elements may have a repeating pattern of pillars with varying diameters, interelement spacings, and/or heights. The repeating pattern of nanopillar deflector elements may be repeated multiple times to provide a metasurface lens, such as a metalens subpixel with a target surface area that corresponds to the surface area of an LED subpixel of an RGB pixel of an RGB LED display. The diameters, interelement spacings, and/or heights of the pillars in each array of nanopillar deflector elements may vary based on the frequency/wavelength/color of the corresponding LED subpixel. Accordingly, a metalens for a single pixel of an RGB display may include three different single-frequency arrays of nanopillar deflector elements that are “stitched” or otherwise positioned adjacent to one another to form a multifrequency metalens with metalens subpixels for each LED pixel. The stitched multifrequency metalens may be replicated for each pixel of the RGB display. In some instances, stitched multifrequency metalenses may exhibit some crosstalk between the different single-frequency arrays of nanopillar deflector elements.

In other embodiments, an entire RGB display may be covered with three different metalens layers. A first metalens layer with a first pattern of nanopillars may be provided to deflect optical radiation having a first frequency. A second metalens layer with a second pattern of nanopillars may be provided to deflect optical radiation having a second frequency. A third metalens layer with a third pattern of nanopillars may be provided to deflect optical radiation having a third frequency. In some instances, the vertical stacking of three metalens layers may reduce the overall efficiency of light transmission due to multi-layer reflections and other losses.

In another embodiment, a multifrequency metalens for a multicolor display (e.g., an RGB display, a two-color display, or another display) may be embodied as an in-plane spatially multiplexed array of frequency-specific nanopillars intermingled with one another. The spatially multiplexed array of frequency-specific nanopillars may comprise a plurality of sub-unit-cells with a number of pillars equal to or greater than the number of independent frequencies to be deflected. The periodicity of the sub-unit-cells is subwavelength and selected for zero-order diffraction. Accordingly, the periodicity of the sub-unit-cells may be selected to be less than the smallest wavelength of the frequencies to be deflected. For example, if the smallest wavelength to be deflected is 550 nanometers, the largest periodicity for zero-order diffraction is approximately 360 nanometers, and so the largest periodicity of the sub-unit-cells is approximately 180 nanometers (e.g., the Nyquist limit). For blue light with a wavelength less than 500 nanometers, the largest periodicity for zero-order diffraction would be even smaller, and accordingly, the largest periodicity of the sub-unit-cells would be smaller still.

In some embodiments, to achieve an acceptable phase shift of each of the independent frequencies to be deflected (e.g., a range from 0 to 2 π), the height of the individual pillars may be slightly taller than in other embodiments to accommodate for relatively close spacing defined by the calculated largest possible periodicity of the sub-unit-cells for zero-order diffraction. For example, a pillar height between approximately 200 nanometers and 400 nanometers may be suitable, depending on the specific frequencies to be deflected. In one example, the individual pillars have a height of approximately 300 nanometers.

For a selected height and periodicity, a simulator or calculation module may simulate or calculate the transmission and transmitted phase shift of each of the frequencies to be deflected for a range of pillar diameters in each sub-unit-cell. Suitable pillar diameters may be selected to achieve target performance metrics and/or controllability. For example, pillar diameters may be selected to provide a transmission of at least 0.7 (e.g., 70%) and a phase shift within a range of 0 to 2 π to provide full control of deflection. In some embodiments and applications, lower or higher transmission thresholds may be acceptable and/or partial deflection control may be sufficient (e.g., less than 2 π phase shift).

The difference between a target field and a simulated field provides a figure of merit that can be calculated as |t_{target}e^{-iϕ}^{_{target}}−tⱼe^{-ϕ}^{ⱼ}|². An optimization algorithm, such as a global optimization algorithm, may be used to determine specific radius (diameter) dimensions for the pillars (or passive deflector elements having another shape) in each sub-unit-cell. A metalens is formed via a repeating pattern of sub-unit-cells with pillars that have varying diameters. The metalens is arranged with respect to the light source to provide the target deflection pattern, as described herein. For example, the metalens may be arranged as a planar layer on top of an LED array.

In one simulation of a design for a dual-frequency response metalens for 650 nanometers and 550 nanometers, a 300 nanometers pillar height was selected with a sub-unit-cell periodicity of 180. The simulated diffraction efficiency of the first order was 0.93 and 0.92 for the wavelengths 550 nanometers and 650 nanometers, respectively. Each repeated unit cell of the simulated metalens provided a phase shift range of more than 2 π via six unique sub-unit-cells with two pillars of varying diameters in each sub-unit-cell.

The generalized descriptions of the systems and methods herein may be utilized and/or adapted for utilization in a wide variety of industrial, commercial, and personal applications. Similarly, the presently described systems and methods may be used in conjunction with or utilize existing computing devices and infrastructures. Some of the infrastructure that can be used with embodiments disclosed herein is already available, such as general-purpose computers, computer programming tools and techniques, digital storage media, and communication links. A computing device or controller may include a processor, such as a microprocessor, a microcontroller, logic circuitry, or the like.

A processor may include one or more special-purpose processing devices, such as application-specific integrated circuits (ASICs), a programmable array logic (PAL), a programmable logic array (PLA), a programmable logic device (PLD), a field-programmable gate array (FPGA), or another customizable and/or programmable device. The computing device may also include a machine-readable storage device, such as non-volatile memory, static RAM, dynamic RAM, ROM, CD-ROM, disk, tape, magnetic, optical, flash memory, or another machine-readable storage medium. Various aspects of certain embodiments may be implemented using hardware, software, firmware, or a combination thereof.

The components of the disclosed embodiments, as generally described and illustrated in the figures herein, could be arranged and designed in a wide variety of different configurations. Furthermore, the features, structures, and operations associated with one embodiment may be applied to or combined with the features, structures, or operations described in conjunction with another embodiment. In many instances, well-known structures, materials, or operations are not shown or described in detail in order to avoid obscuring aspects of this disclosure. The embodiments of the systems and methods provided within this disclosure are not intended to limit the scope of the disclosure but are merely representative of possible embodiments. In addition, the steps of a method do not necessarily need to be executed in any specific order or even sequentially, nor do the steps need to be executed only once.

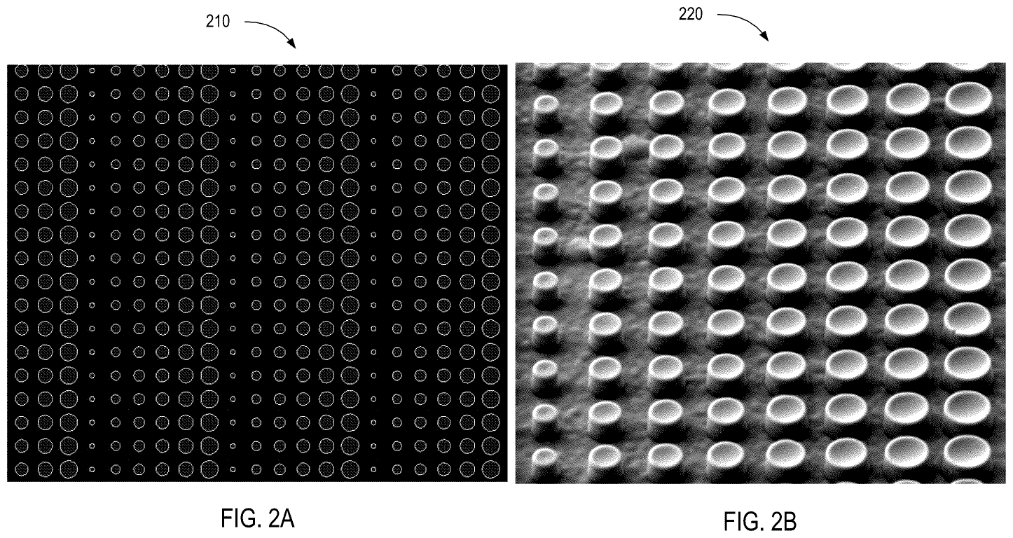

FIG. 2A illustrates a top-down view of an example representation of a pattern of deflector elements 210 for a metalens structure, according to one embodiment. As illustrated, a uniform square grid of deflector elements 210 may pattern the deflector elements 210 with uniform spacings between adjacent or nearest neighbor deflector elements. Moreover, the deflector elements 210 may be configured with uniform heights. In the illustrated example, the deflector elements 210 comprise circular pillars arranged in a repeating pattern of pillar diameters.

FIG. 2B illustrates an enlarged perspective view of the example representation of the pattern of deflector elements in the metalens of FIG. 2A, according to one embodiment. As illustrated, the array of deflector elements 220 includes a uniformly spaced arrangement of circular pillars extending from a substrate. The deflector elements 220 have different pillar diameters that increase along one dimension (left to right) and are constant along the other dimension (top to bottom). Alternative patterns of pillar diameters may be used to achieve target deflection patterns.

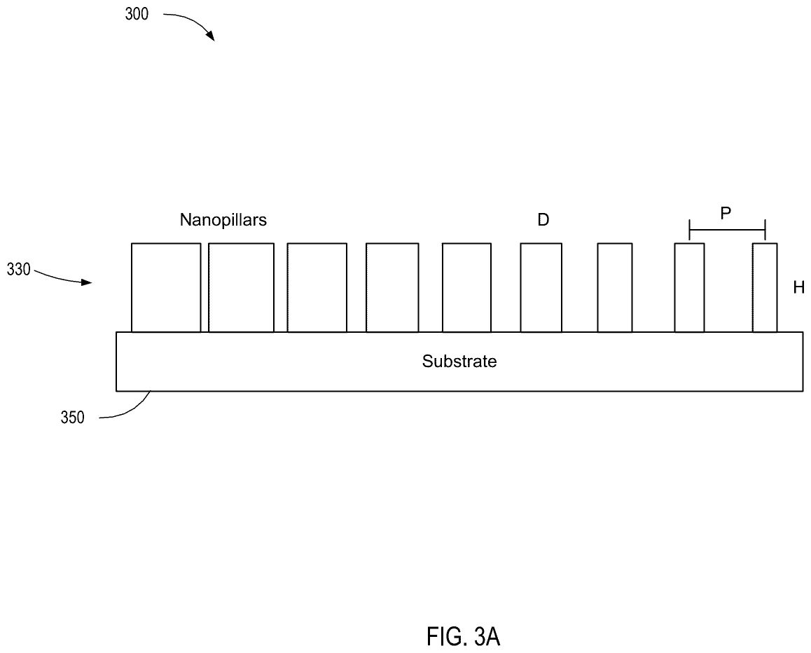

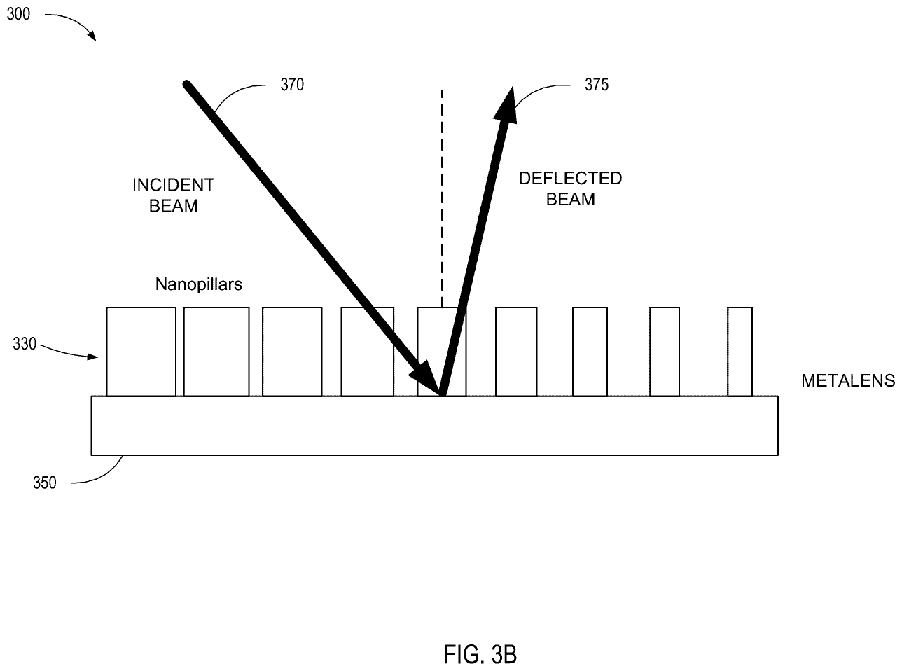

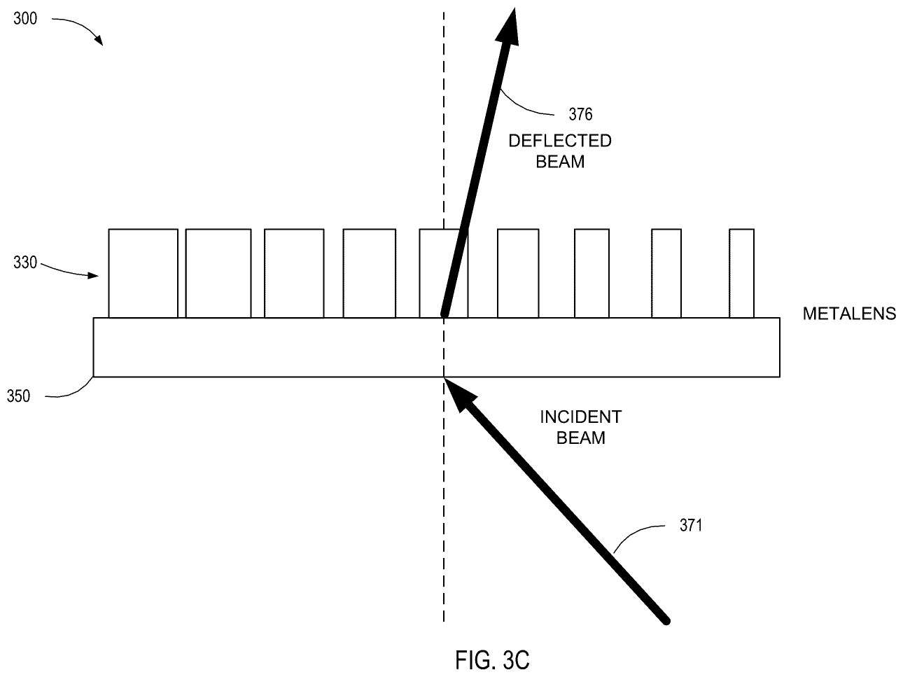

FIG. 3A illustrates an example block diagram of a side view of a metalens 300 with nanopillar deflector elements 330 positioned on a substrate 350, according to one embodiment. As illustrated, the nanopillar deflector elements 330 may have a uniform height, H, and varying diameters, D. In the illustrated example, the nanopillar deflector elements 330 are evenly spaced with a nearest neighbor on-center spacing distance, P. The spacing between the centers of adjacent or nearest neighbor nanopillars may be constant despite the varying diameters of the pillars. As described herein, the dimensions, pattern, and spacings of the nanopillars are selected to achieve a target deflection pattern (e.g., angle of deflection, dispersion, collimation, convergence, etc.) and frequency response (e.g., target operational bandwidth of optical radiation).

FIG. 3B illustrates the example block diagram of the metalens 300 of FIG. 3A operating to reflect incident optical radiation 370 as deflected optical radiation 375 at a target deflection angle, according to one embodiment.

FIG. 3C illustrates the example block diagram of the metalens 300 of FIG. 3A transmissively steering incident optical radiation 371 as deflected optical radiation 376 at a target deflection angle, according to one embodiment.

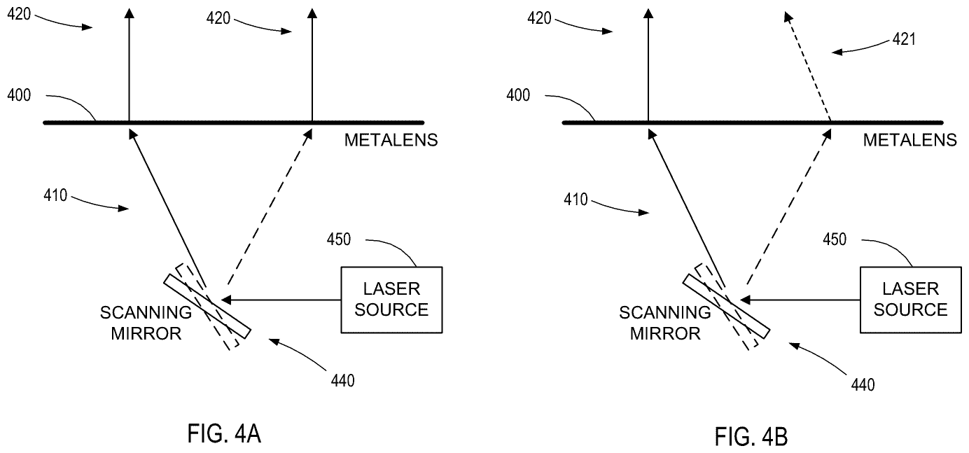

FIGS. 4A-4B illustrate metalenses used in conjunction with laser-scanning subsystems, according to various embodiments. As illustrated and labeled, a laser source 450 may transmit coherent optical radiation to a scanning mirror 440 that is mechanically moved between a first position and a second position to scan the laser along one dimension (left to right on the page). In FIG. 4A, optical radiation 410 from the laser source 450 is incident on the left side of the metalens at a first angle of incidence when the scanning mirror 440 is rotated counterclockwise (shown in solid lines). Optical radiation 410 from the laser source is incident on the right side of the metalens at a second angle of incidence when the scanning mirror is rotated clockwise (shown in dashed lines).

As illustrated, the metalens may be configured to transmissively deflect the incident optical radiation as collimated deflected optical radiation 420 that transmits in a uniform direction along the length of the metalens 400. In such an embodiment, the array of deflector elements may be patterned on a substrate with dimensions, spacings, and heights to compensate for the different angle of incidence of the optical radiation 410 as the scanning mirror is rotated.

In an alternative embodiment illustrated in FIG. 4B, the metalens may comprise an array of deflector elements patterned on a substrate with dimensions, spacings, and heights to transmit output optical radiation at different exit angles 420 and 421 depending on the location at which the optical radiation was received. The effective deflection pattern of the metalens may be selected to achieve a target optical objective, such as forming multiple depth planes, pupil replication, or expansion of the viewing eyebox.

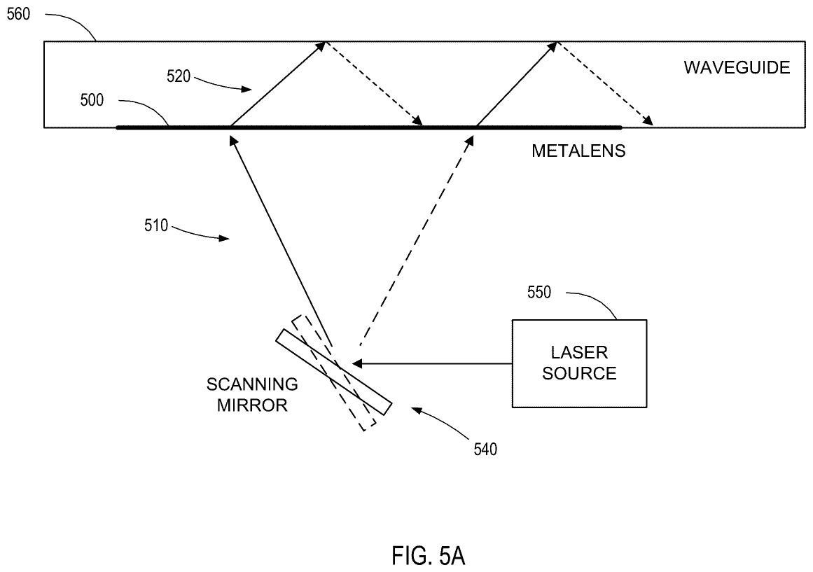

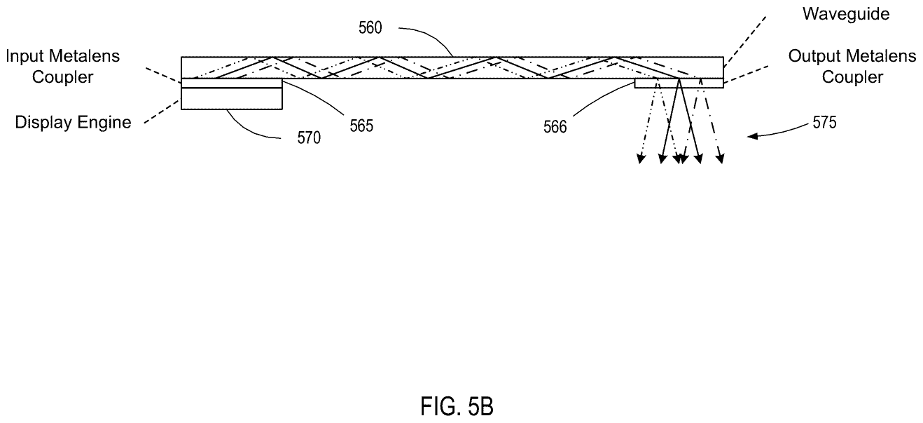

FIG. 5A illustrates an example system with a metalens 500 and waveguide 560 used in conjunction with a laser scanning subsystem that includes a laser source 550 and a scanning mirror 540, according to one embodiment. According to the illustrated embodiment, the metalens 500 may provide the equivalent functionality of injection optics in a laser-scanning illumination engine. In some embodiments, the metalens (or just the array of deflector elements) may be directly fabricated on the waveguide substrate. Given the subwavelength thickness of the metalens 500, the system may be much more compact and/or efficient than a similar system using traditional injection optics. The metalens 500 may deflect received optical radiation 510 into the waveguide 560 for total internal reflection and/or transmission, at 520, along the length of the waveguide 560.

FIG. 5B illustrates an example display system that utilizes an input metalens coupler 565 and an output metalens coupler 566 in conjunction with a waveguide 560, according to one embodiment. A display engine 570 may generate optical radiation as part of an RGB display (e.g., via an LED array of RGB pixels). The input metalens coupler 565 may couple the generated RGB optical radiation for transmission along the length of the waveguide 560. The output metalens coupler 566 may receive the transmitted optical radiation and decouple it from the waveguide 560 for visualization by a user (e.g., via frequency selective focusing to a target plane).

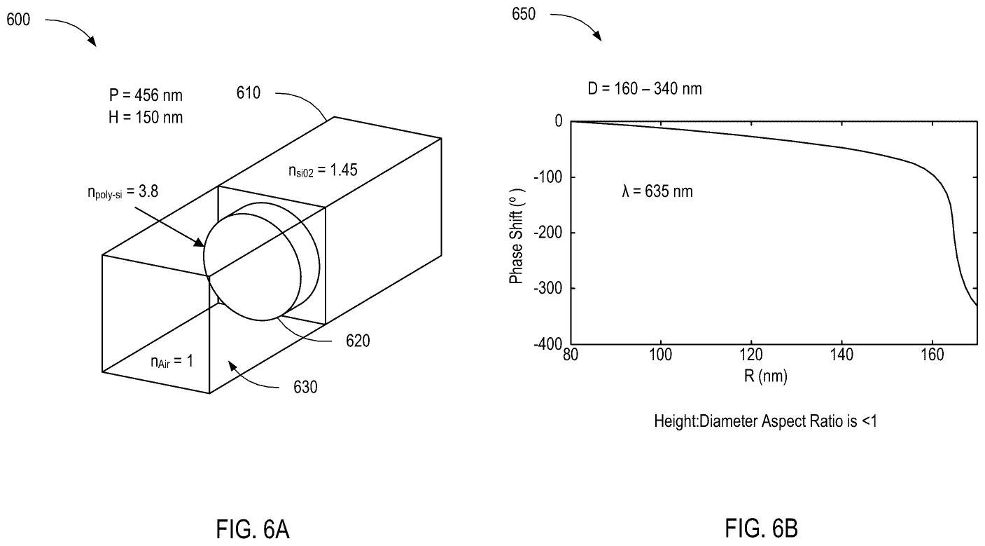

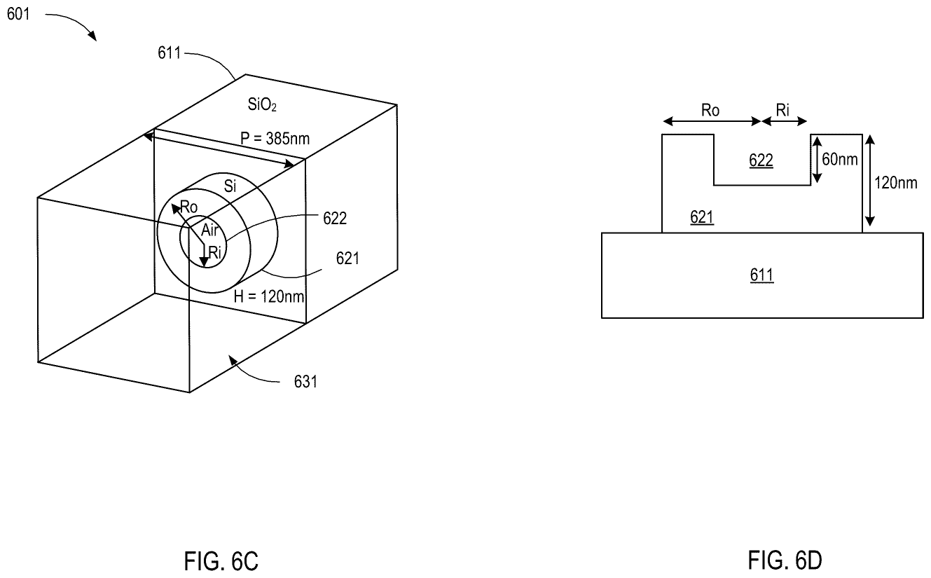

FIG. 6A illustrates an example of a unit cell 600 of a metalens with a cylindrical deflector element or “nanopillar” 620 for use with a red laser, according to one embodiment. The nanopillar 620 extends from a substrate 610 into another medium, such as air 630, another gas, or a vacuum. The air 630, other gas, or vacuum may be encapsulated within an enclosure as illustrated, or the nanopillar 620 may extend into free space, which may be filled with air during normal use in some usage scenarios.

In the illustrated example, the spacing, P, between the centers of adjacent nanopillars 620 is 456 nanometers. The height, H, of each nanopillar 620 may be 150 nanometers. The diameters, D, of the nanopillars 620 in the array of nanopillars may vary from approximately 160 nanometers to 340 nanometers. The specific pattern of diameters of nanopillars, spacings, and heights may be selected to attain a target deflection pattern (e.g., angle of deflection, dispersion, collimation, convergence, etc.).

In the illustrated example, the substrate 610 may be SiO₂ with an index of refraction of approximately 1.45. The deflector element, illustrated as cylindrical nanopillar 620, may be poly-Si with an index of refraction of approximately 3.8. The air 630 or other surrounding fluid (gas, oil, liquid, etc.) or other material may have a relatively low index of refraction. For example, the air 630 may have an index of refraction of approximately 1.0.

FIG. 6B illustrates a graph 650 of phase shift values for various diameters of a cylindrical deflector element (i.e., nanopillar) in a unit cell of a metalens illuminated by a red laser with a 635-nanometer wavelength, according to one embodiment. As illustrated, for diameters between 160 nanometers and 340 nanometers, the incident red laser light exhibits a phase shift of between approximately 100 degrees and 360 degrees.

For coherent illumination sources, such as laser illumination sources, each of the deflector elements in an array of deflector elements may be cylindrical (e.g., nanopillars) and operate in the resonance mode with a height, H, that is less than or equal to the smallest diameter, D, in the array of deflector elements. Such deflector elements can be described as having an aspect ratio of less than one (e.g., H/D<1). Accordingly, the deflector elements of a metalens illuminated using laser light may be cylindrical nanopillars and operate in the resonance mode with an aspect ratio of less than approximately one.

FIG. 6C illustrates another example of a unit cell 601 of a metalens with a cylindrical deflector element 621 with a cylindrical cavity 622 formed therein, according to one embodiment. The cylindrical deflector element 621 may extend perpendicular to (i.e., normal to) the plane of the substrate 611. The interelement spacing, P, of the example unit cell 601 in the metalens is 385 nanometers and the cylindrical deflector element 621 may extend from the substrate 611 to a height of approximately 120 nanometers. A cylindrical cavity 622 is formed in the cylindrical deflector element 621. The cylindrical cavity 622 may have a radius, Ri, that is smaller than (e.g., a percentage or ratio of) the radius, R₀, of the cylindrical deflector element 621.

The cylindrical deflector element 621 may extend into a region of free space 631 that is filled with air or another fluid. The diameter of the cylindrical deflector element 621 and the diameter of the cylindrical cavity 622 may each be selected based on a target frequency response. A metalens may be formed as a two-dimensional array of unit cells of cylindrical deflector elements 621 having varying diameters within a range of diameters selected for a target deflection pattern within an operational frequency range.

FIG. 6D illustrates a side cutaway view of the example unit cell of FIG. 6C, according to one embodiment. As illustrated, the cylindrical deflector element 621 extends from the substrate 611 with a height, H, of 120 nanometers. In the illustrated example, the cylindrical cavity 622 has a depth of 60 nanometers. Alternative cavity depths and ratios of cavity depths relative to deflector element heights may be utilized based on the target deflection pattern and frequency response.

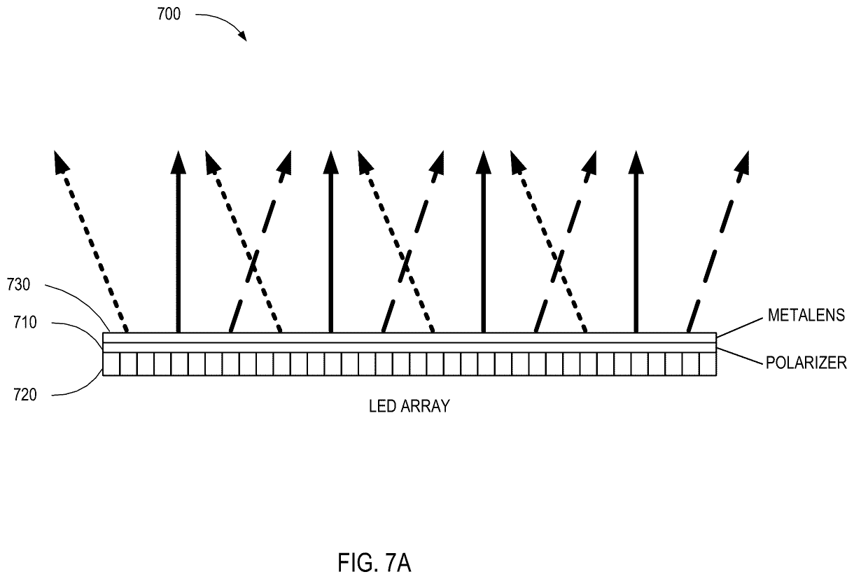

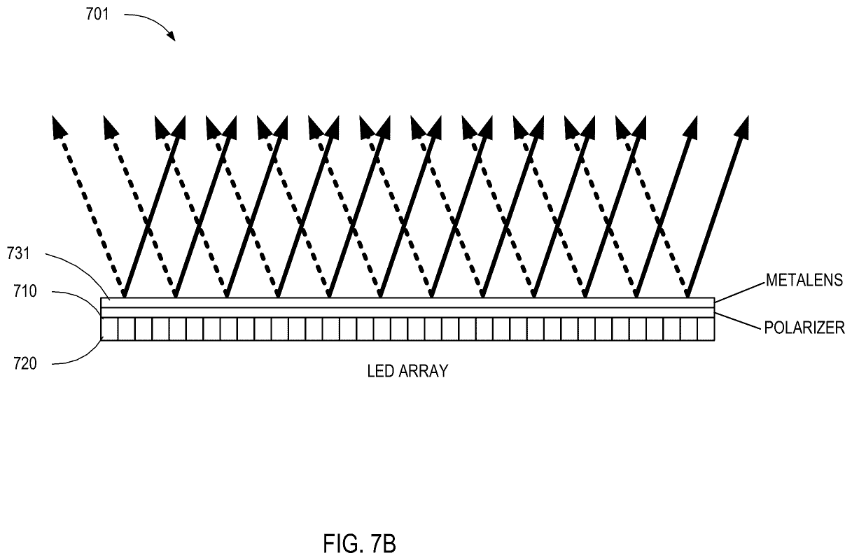

FIG. 7A illustrates an example of a display system 700 that includes a metalens 730, an array of light-emitting diodes (LED array) 720, and a polarizer or polarizing filter 710. The display system 700 may be specifically configured to redirect optical radiation to form a light-field, according to one embodiment. As illustrated, optical radiation from different pixels is transmitted in different directions to provide a user with different images depending on the location of the user with respect to the visual field of the display system 700.

According to various embodiments, any of a wide variety of illumination sources may be utilized, including LEDs, microLEDs, OLED, and the like. As compared to laser light sources, LED illumination sources have a relatively broad frequency band that is not spatially coherent. The incoherent light from the LED array 720 is polarized by the polarizing filter 710. The polarized light from the polarization filter 710 is deflected by the metalens 730. The metalens 730 may include pillars with rectangular or cylindrical shapes that are polarization-dependent to receive and deflect the polarized optical radiation after it passes through the polarizing filter 710. In some embodiments, the metalens 730 and the polarizing filter 710 may be laminated on top of, for example, a two-dimensional array of LEDs.

FIG. 7B illustrates an example of a display system 701 with a metalens 731, the LED array 720, and a polarizer or polarizing filter 710 to subdivide optical radiation from each pixel or subpixel of the LED array 720 into two different directions for pixel or subpixel pupil replication, according to one embodiment. The deflector elements of the metalens 731 are illuminated by the incoherent light from the LED array 720 after it is passed through the polarizing filter 710. As previously described, the deflector elements may be polarization-dependent rectangular or cylindrical pillars that operate in the resonance mode with a height: diameter aspect ratio of less than approximately one. That is, the height of each deflector element may be less than the diameter of each respective deflector element. In some instances, the heights of the deflector elements in the metalens are all the same (i.e., constant) and the constant height of the deflector element is less than the smallest diameter used in the array of deflector elements forming the metalens.

In alternative embodiments, a metalens may include polarization-dependent rectangular pillars, but omit the polarizer 710 shown in FIG. 7B. In such embodiments, the metalens is responsive to deflect optical radiation of one or more unique polarization states. In one example embodiment, the metalens may include rectangular pillars responsive to one polarization state intermingled (e.g., periodically or randomly) with rectangular pillars responsive to a second polarization state. A metalens with intermingled rectangular pillars responsive to two or more different polarization states may perform different lensing functions based on the different polarization states of the incident optical radiation. For example, a metalens may be configured to deflect right-hand circular polarized light at a first angle (e.g., to a right eye of a user) and deflect left-hand circular polarized light at a second angle (e.g., to a left eye of a user).

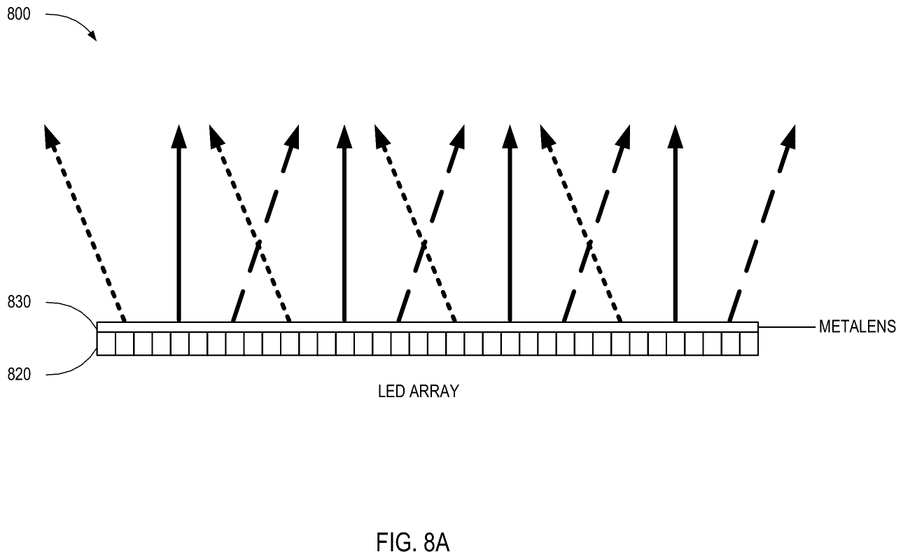

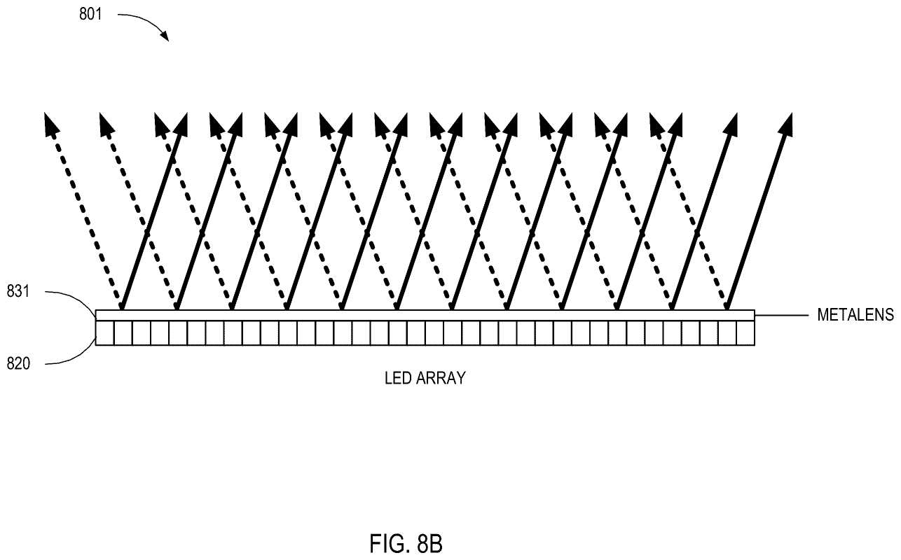

FIG. 8A illustrates an example of a display system 800 with a metalens 830 that works in conjunction with the LED array 820, but without a polarizer or polarizing layer, according to one embodiment. With the omission of the polarizing filter 710 of FIG. 7A, the deflector elements of the modified metalens 830 may have circular profiles (e.g., cylindrical deflector elements) and be polarization-independent. As previously noted, optical radiation from the LED array 820 exhibits polarization incoherence, spectral incoherence, and spatial incoherence. In such embodiments, as described herein, the deflector elements may be designed and configured to accommodate the incoherent and unpolarized light from the LED array 820.

By way of comparison, the deflector elements of a metalens which are illuminated using laser light, according to various embodiments described herein, may be cylindrical (e.g., nanopillars) and operate in the resonance mode with a height: diameter aspect ratio of approximately less than one. In contrast, the deflector elements of a metalens illuminated using incoherent light (e.g., from an array of LEDs) passed through a polarization filter may be rectangular (polarization-dependent) and operate in the resonance mode with a height: diameter aspect ratio of less than approximately one.

In contrast with the previously described embodiments, the deflector elements of the metalens 830, which are illuminated using incoherent light without a polarizing filter, as illustrated in FIG. 8A, may be cylindrical, may be polarization-independent, and may operate in the waveguide mode with a height that is greater than the largest deflector element diameter used in the array of deflector elements. Accordingly, the height: diameter aspect ratio is greater than one. For example, the height of each nanopillar of the metalens 830 may be between approximately 1.1 and 8.0 times the diameter of the largest nanopillar used in the array of nanopillars, depending on the specific wavelength of light and target phase shift. The illustrated display system 800 utilizes feature sizes that are in the tens or hundreds of nanometers and is therefore compatible with the highest pixel density displays currently available, including microLED displays.

FIG. 8B illustrates an example of a display system 801 with a metalens 831 and an LED array 820 without a polarizer, according to one embodiment. In the illustrated embodiment, the metalens 831 may be configured with circular or cylindrical nanopillars with an aspect ratio greater than one to operate in the waveguide mode. The specific diameters and spacings of the nanopillars of the metalens 831 may be selected to subdivide optical radiation from each pixel of the LED array 820 into two different directions for subpixel pupil replication, according to one embodiment.

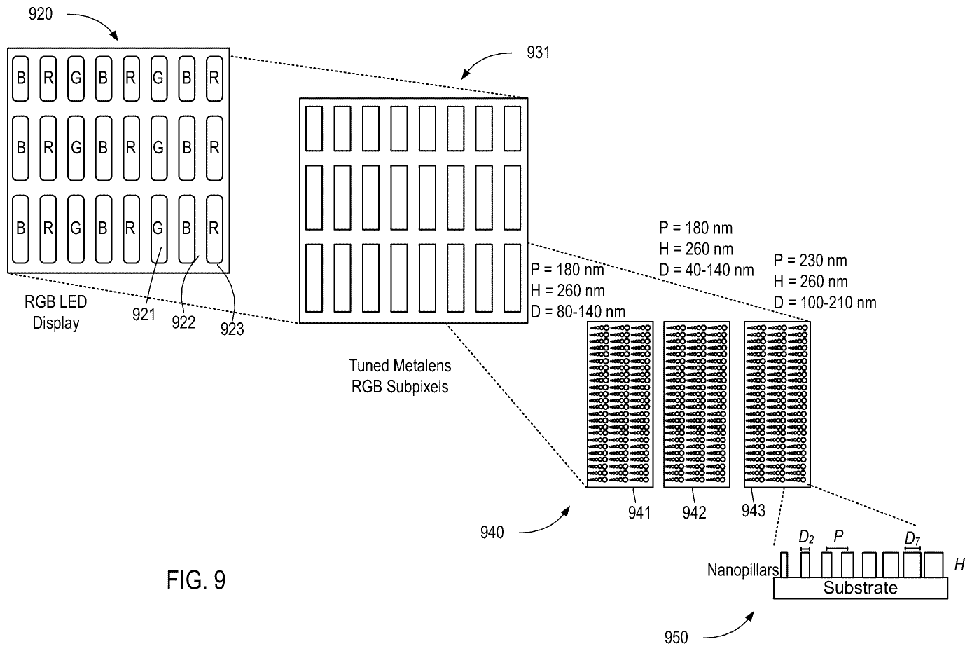

FIG. 9 illustrates a portion of an example LED display 920 and various levels of detail of a tuned metalens 931 with RGB pixels, according to one embodiment. As illustrated, the LED display 920 includes red, green, and blue (RGB) subpixels that together form an RGB pixel. The tuned metalens 931 includes a two-dimensional array of deflector elements with a pattern of diameters and interelement spacings selected to produce a target deflection pattern (e.g., a reflection transmission angle or refraction transmission angle) for each LED subpixel. For example, a two-dimensional arrangement of deflector elements is different for a blue subpixel than it is for the red and green subpixels within the same RGB pixel. The metalens 931 can be described as having tuned metalens subpixels that correspond to the LED subpixels of the LED display 920.

In some embodiments, as described herein in the context of pixel or subpixel duplication, light field generation, 3D-image generation, and/or the like, light from each LED subpixel in a given RGB pixel may be directed in the same direction, different directions, or subdivided for transmission to two different locations.

Simplified patterns of deflector elements 940 are shown for each of a green subpixel metalens 941, a blue subpixel metalens 942, and a red subpixel metalens 943. Each subpixel metalens 941, 942, and 943 includes deflector elements with repeating patterns of diameters and interelement spacings selected to provide a target deflection angle. An example of the repeating pattern of nanopillars on a substrate 950 is illustrated as well. The number of pillars, pattern of diameters, range of diameters, and other characteristics of the individual pillars in each repeating pattern may vary according to the specific operational frequency and target deflection angle or deflection pattern.

The following specific examples of on-center spacings, P, heights, H, and diameters, D, are provided with respect to the patterns of deflector elements 940 and the example repeating pattern of nanopillars on the substrate 950. According to one specific embodiment, the deflector elements of the green subpixel metalens 941 may have a height, H, of approximately 210 to 280 nanometers and on-center spacings, P, of approximately 160 to 2000 nanometers for green light having a wavelength of, for example, approximately 550 nanometers. The height, H, and on-center spacings, P, may be adjusted or specified based on the specific frequency or frequency range of the green light.

In the illustrated embodiment, the deflector elements of the green subpixel metalens 941 have a height, H, of approximately 260 nanometers with on-center spacings, P, of approximately 180 nanometers. In a different embodiment, the deflector elements of the green subpixel metalens 941 may be configured with a height, H, of approximately 220 nanometers with on-center spacings, P, of approximately 190 nanometers. The repeating pattern of deflector elements may include deflector elements having diameters between 80 nanometers and 150 nanometers, for example. The total size (length and width) of the green subpixel metalens 941 may be selected to correspond to the dimensions of a green subpixel 921 of the LED display 920. In applications in which the metalens 931 is used for imaging, the total size (length and width) of the green subpixel metalens 941 may be selected to correspond to the dimensions of a green photosensor of an imaging sensor array.

In the illustrated example, the diameters, D, of the nanopillars in each repeating row of nanopillars in the green subpixel metalens 941 range from approximately 80 nanometers and 140 nanometers to attain phase shifts approaching or exceeding a 2 π range. As described above, some embodiments may use a wider range of diameters (e.g., 80 nanometers to 150 nanometers) to attain a suitable range of attainable phase shifts for a particular application. A target pattern of phase shifts across the two-dimensional arrangement of repeating rows of nanopillars in the green subpixel metalens 941 may be selected to achieve a target deflection pattern. Furthermore, the number of nanopillars in each row of repeating nanopillars of varying diameters may be determined based on the target deflection pattern and the specific frequency or frequency range of green light. The total number of rows and columns of repeating patterns of nanopillars of varying diameters may depend on the total length and width of the green subpixel metalens 941.

The deflector elements of the blue subpixel metalens 942 may have a height, H, of approximately 210 to 260 nanometers and on-center spacings, P, of approximately 160 to 200 nanometers for blue light having a wavelength of, for example, approximately 490 nanometers. Again, the height, H, and on-center spacings, P, may be adjusted or specified based on the specific frequency or frequency range of the blue light. In the illustrated embodiment, the deflector elements of the blue subpixel metalens 942 have a height, H, of approximately 260 nanometers with on-center spacings, P, of approximately 180 nanometers. The diameters, D, of the nanopillars in each repeating row of nanopillars in the blue subpixel metalens 942 may range between approximately 40 nanometers and 140 nanometers to attain phase shifts exceeding a 2 π range.

A target pattern of phase shifts across the two-dimensional arrangement of repeating rows of nanopillars in the blue subpixel metalens 942 may be selected to achieve a target deflection pattern (e.g., reflection angle or refraction angle). Furthermore, the number of nanopillars in each row of repeating nanopillars of varying diameters may be determined based on the target deflection pattern and/or the specific frequency or frequency range of blue light. The total number of rows and columns of repeating patterns of nanopillars of varying dimensions may depend on the total length and width of the blue subpixel metalens 942.

In one specific embodiment, the deflector elements of the blue subpixel metalens 942 may be configured with a height, H, of approximately 220 nanometers, on-center spacings, P, of approximately 180 nanometers, and repeating pattern of deflector element diameters between 80 nanometers and 140 nanometers. As in other embodiments, the total size (length and width) of the blue subpixel metalens 942 may be selected to correspond to the dimensions of a blue subpixel 922 of the LED display 920. In applications in which the metalens 931 is used for imaging, the total size (length and width) of the blue subpixel metalens 942 may be selected to correspond to the dimensions of a blue photosensor of an imaging sensor array.

The deflector elements of the red subpixel metalens 943 may have a height, H, of approximately 210 to 280 nanometers and on-center spacings, P, of 210-280 nanometers for red light having a wavelength of, for example, approximately 635nanometers. In the specific illustration, the red subpixel metalens 943 has a height, H, of 260 nanometers and on-center spacings, P, of 230 nanometers. Again, the height, H, and on-center spacings, P, may be adjusted or specified based on the specific frequency or frequency range of the red light. Moreover, the total size (length and width) of the red subpixel metalens 943 may be selected to correspond to the dimensions of a red subpixel 923 of the LED display 920. In applications in which the metalens 931 is used for imaging, the total size (length and width) of the red subpixel metalens 943 may be selected to correspond to the dimensions of a red photosensor of an imaging sensor array.

In the illustrated embodiment, the deflector elements of the red subpixel metalens 943 have a height, H, of approximately 260 nanometers with on-center spacings, P, of approximately 230 nanometers. In a different embodiment, the deflector elements of the red subpixel metalens 943 may be configured with a height, H, of approximately 220 nanometers with on-center spacings, P, of approximately 250 nanometers. The repeating pattern of deflector elements may include deflector elements having diameters between 80 nanometers and 220 nanometers, for example.

In the illustrated example, the diameters, D, of the nanopillars in each repeating row of nanopillars in the red subpixel metalens 943 range from approximately 100 nanometers to 210 nanometers to attain phase shifts exceeding a 2 π range. In a different embodiment, the diameters of the nanopillars used in the red subpixel metalens 943 range from approximately 80 nanometers to 220 nanometers to provide a wider range of attainable phase shifts. A target pattern of phase shifts across the two-dimensional arrangement of repeating rows of nanopillars in the red subpixel metalens 943 may be selected to achieve a target deflection pattern (e.g., reflection angle or refraction angle). Furthermore, the number of nanopillars in each row of repeating nanopillars of varying diameters may be determined based on the target deflection pattern and/or the specific frequency or frequency range of red light. The total number of rows and columns of repeating patterns of nanopillars of varying dimensions may depend on the total length and width of the red subpixel metalens 943.

In the illustrated example, as described above, the heights of the nanopillars for each of the red, green, and blue subpixel metalenses 943, 941, and 942 are the same. In alternative embodiments, the heights of the nanopillars of each different color subpixel metalens may be different. Additionally, the example LED display 920 includes green, blue, and red pixels 921, 922, and 923. However, it is appreciated that alternative display color schemes are possible, as are LED displays that include more than three subpixels per pixel (e.g., MultiPrimary displays, such as those using RGBY, RGBW, or RGBYC subpixels). In such embodiments, a tuned metalens may include any number of “subpixel metalenses” or “metalens subpixels” to match the number and/or colors of subpixels used in the MultiPrimary LED display.

A row of nanopillars of varying widths that is repeated along the length and/or width of a given subpixel metalens may be referred to as a nanopillar row. The on-center spacing, P, of adjacent nanopillars in a nanopillar row may be constant, as described herein. In some embodiments, on-center spacing, P, of adjacent nanopillars in a nanopillar row may be a function of the frequency of light to be deflected (e.g., refracted or reflected). Accordingly, on-center spacing, P, of adjacent nanopillars in a nanopillar row for a subpixel metalens for a blue subpixel may be different than the on-center spacing, P, of adjacent nanopillars in a nanopillar row for a subpixel metalens for a red or green subpixel.

The spacing between nanopillars in adjacent nanopillar rows (e.g., across a width of a subpixel metalens or along the length of the subpixel metalens) may be the same as the on-center spacing, P, of adjacent nanopillars in an individual nanopillar row of the subpixel metalens. Alternatively, the spacing between nanopillars in adjacent nanopillar rows (e.g., across a width of a subpixel metalens or along the length of the subpixel metalens) may be different than the on-center spacing, P, of adjacent nanopillars in an individual nanopillar row of the subpixel metalens.

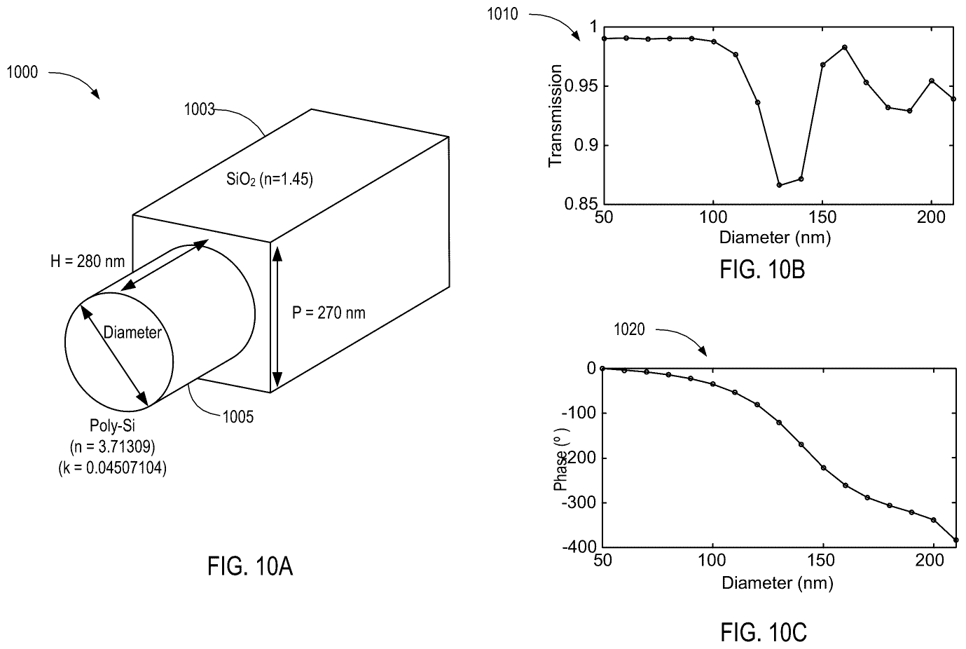

FIG. 10A illustrates an example unit cell 1000 of a red metalens subpixel, according to one embodiment. As illustrated, a poly-Si cylindrical deflector element 1005 extends from a SiO₂ substrate 1003 with a height of 280 nanometers. The on-center interelement spacing of the array of unit cells forming the red metalens subpixel may be 270 nanometers. The red metalens subpixel may include unit cells with deflector elements 1005 having diameters ranging from 80 nanometers to 180 nanometers to attain phase shifts exceeding a 2 π range.

FIG. 10B illustrates a graph 1010 of transmission values (Y-axis) for various diameters (X-axis) of a cylindrical deflector element in a unit cell of a metalens for a red subpixel of an LED display with a wavelength of approximately 635 nanometers, according to one embodiment. As illustrated, minimum transmission values exceed 0.85 for all diameters within the range of diameters that allows for a phase shift between 0 and 2 π.

FIG. 10C illustrates a graph 1020 of various phase shift values (Y-axis) for various diameters (X-axis) of a cylindrical deflector element for a red subpixel, according to one embodiment. As illustrated, various possible ranges of deflector element diameters could be used to attain a phase shift range of 2 π. A range of diameters between approximately 80 nanometers and 180 nanometers provides for a phase shift range of 2 π.

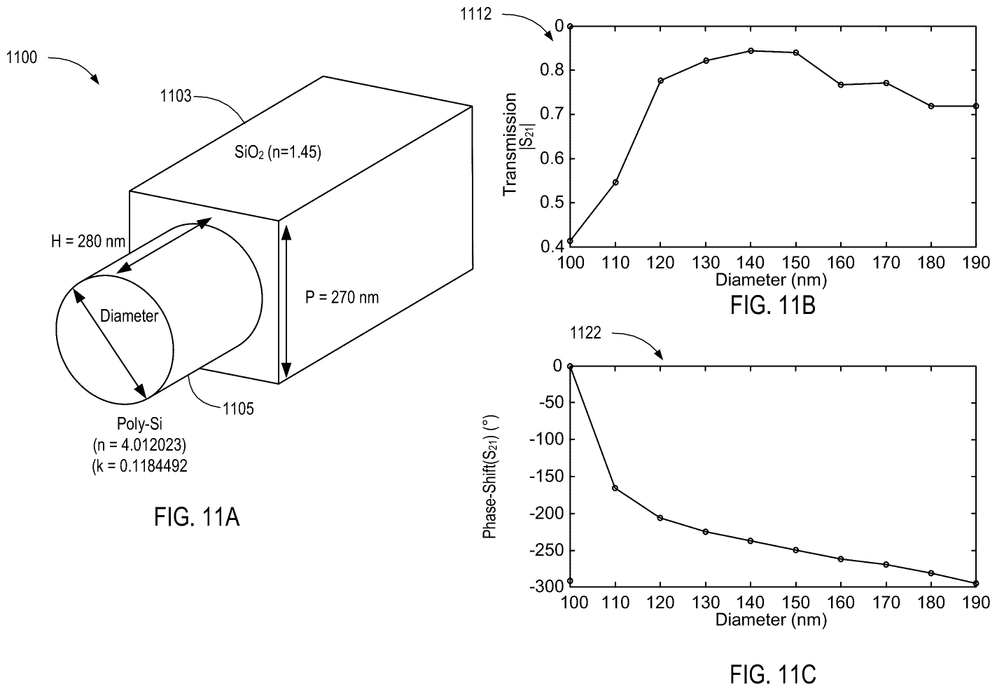

FIG. 11A illustrates an example unit cell 1100 of a green metalens subpixel, according to one embodiment. In the illustrated example, a poly-Si cylindrical deflector element 1105 extends from a SiO₂ substrate 1103 with a height of 280 nanometers. The on-center interelement spacing of the array of unit cells forming the green metalens subpixel may be 270 nanometers. Accordingly, the interelement spacing and the heights of the deflector elements of the red (1003 in FIG. 10A) and green (1103 in FIG. 11A) deflector elements may be the same. However, the green metalens subpixel may include unit cells with deflector elements 1105 having diameters ranging from 80 nanometers to 140 nanometers to attain phase shifts approaching a 2 π range. Smaller ranges of diameters may be utilized in applications where phase shift ranges of less than 2 π are sufficient.

FIG. 11B illustrates a graph 1112 of transmission values (Y-axis) for various diameters (X-axis) of a cylindrical deflector element in a unit cell of a metalens for a green subpixel of an LED display with a wavelength of approximately 550 nanometers, according to one embodiment. As illustrated, using a range of diameters between 120 nanometers and 190 nanometers may maintain higher transmission efficiencies that are attainable using smaller diameters.

FIG. 11C illustrates a graph 1122 of various phase shift values (Y-axis) for various diameters (X-axis) of the cylindrical deflector element for the green subpixel, according to one embodiment. By comparing FIGS. 11B and 11C, it can be understood that a design decision of the range of diameters to use in the green metalens subpixel must balance transmission efficiency with the available phase shift range. A smaller range of available phase shifts may provide for more efficient transmission, while a larger range of available phase shift may result in less efficient transmission.

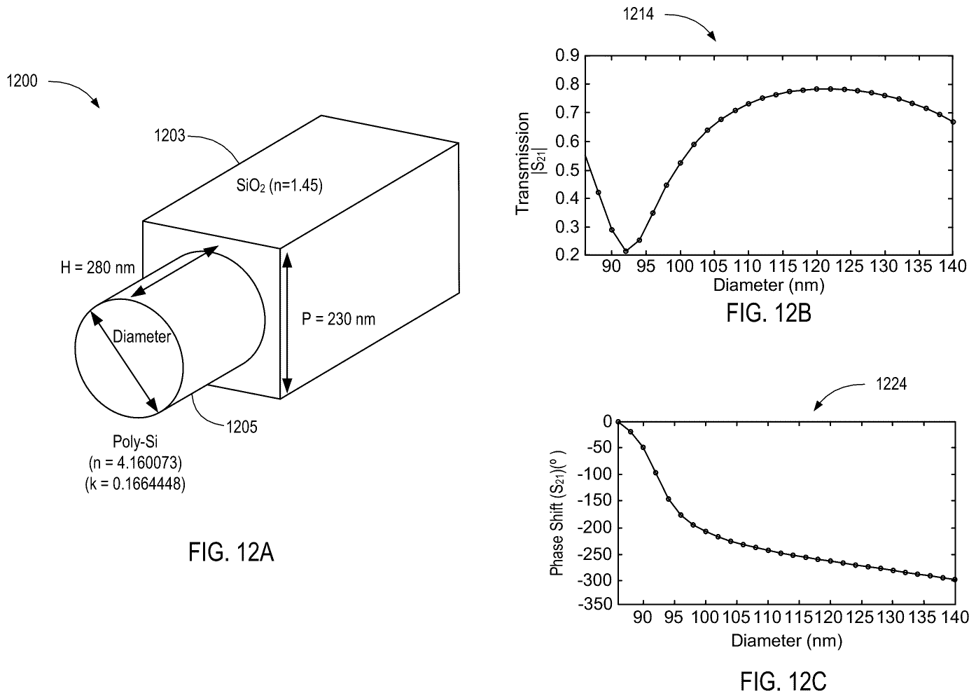

FIG. 12A illustrates an example unit cell 1200 of a blue metalens subpixel, according to one embodiment. In the illustrated example, a poly-Si cylindrical deflector element 1205 extends from a SiO₂ substrate 1203 with a height of 280 nanometers. The on-center interelement spacing of the array of unit cells forming the blue metalens subpixel may be 230 nanometers. The blue metalens subpixel may include unit cells with deflector elements 1205 having diameters ranging from 40 nanometers to 140 nanometers to attain phase shifts approaching a 2 π range.

FIG. 12B illustrates a graph 1214 of transmission values (Y-axis) for various diameters (X-axis) of a cylindrical deflector element in a unit cell of a metalens for a blue subpixel of an LED display with a wavelength of approximately 490 nanometers, according to one embodiment.

FIG. 12C illustrates a graph 1224 of various phase shift values (Y-axis) for various diameters (X-axis) of the cylindrical deflector element for the blue subpixel, according to one embodiment.

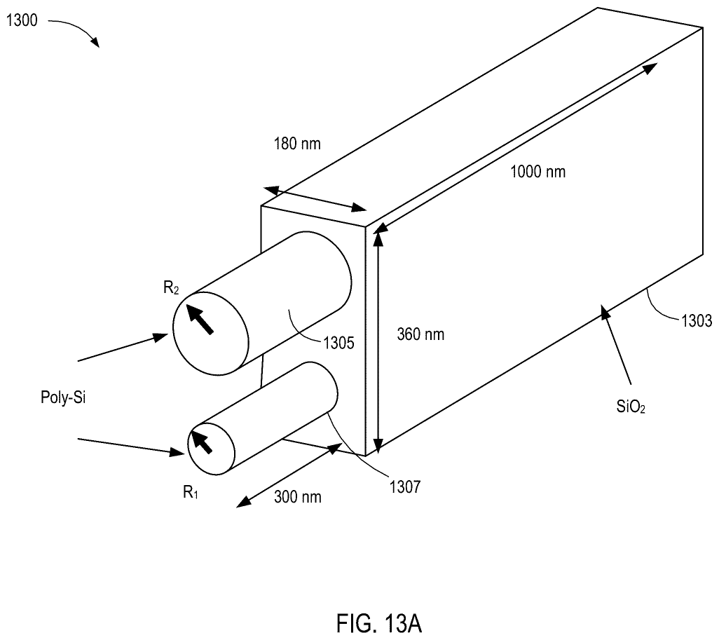

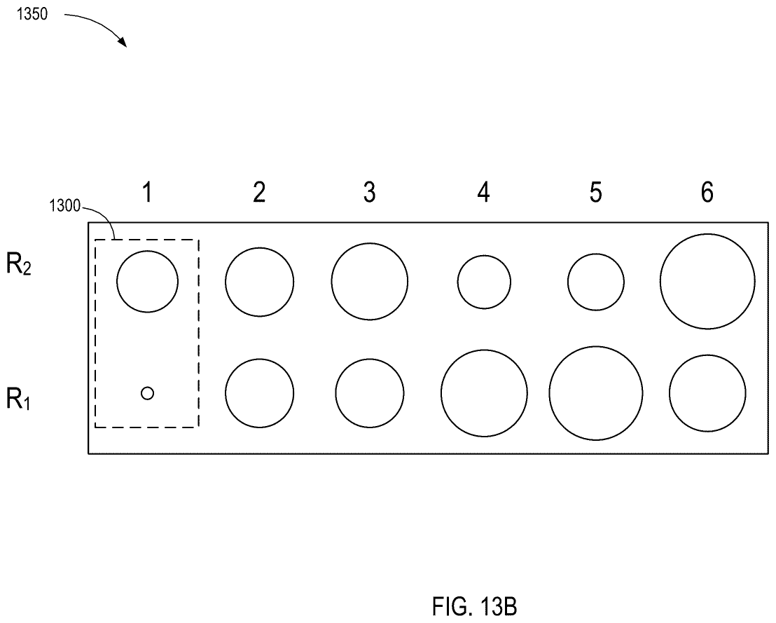

FIG. 13A illustrates an example of a unit-cell 1300 with two deflector elements 1305 and 1307 for a dual-frequency response, according to one embodiment. The sub-unit-cell 1300 is configured for zero-order diffraction of 550-nanometer and 650-nanometer optical radiation. As illustrated, the largest periodicity for zero-order diffraction is approximately 360 nanometers, and the largest periodicity of the unit-cell 1300 is 180 nanometers. Each of the two pillars 1305 and 1307 in the unit-cell 1300 have a height of approximately 300 nanometers. The pillars 1305 and 1307 extend from a substrate 1303, such as a SiO₂ substrate.

The difference between the target field and the simulated field provides a figure of merit that can be calculated as |t_{target}e^{-iϕ}^{_{target}}−tⱼe^{-ϕ}^{ⱼ}|². An optimization algorithm, such as a global optimization algorithm, may be used to determine specific radius (diameter) dimensions for the pillar(s) in each sub-unit-cell.

FIG. 13B illustrates a simplified example multicell metalens 1350 with multiple unit cells 1300. As described in conjunction with FIG. 13A, the multicell metalens 1350 provides a dual-frequency response, according to one embodiment. The multicell metalens 1350 is formed using a repeating pattern of the unit-cells 1300 described in FIG. 13A, but with pillars 1305 and 1307 of varying diameters. Multiple multicell metalenses 1350 can be combined in a one-dimensional array or a two-dimensional array to form a larger one-dimensional metalens, a larger two-dimensional metalens, a metalens pixel with target dimensions, or a metalens subpixel with target dimensions.

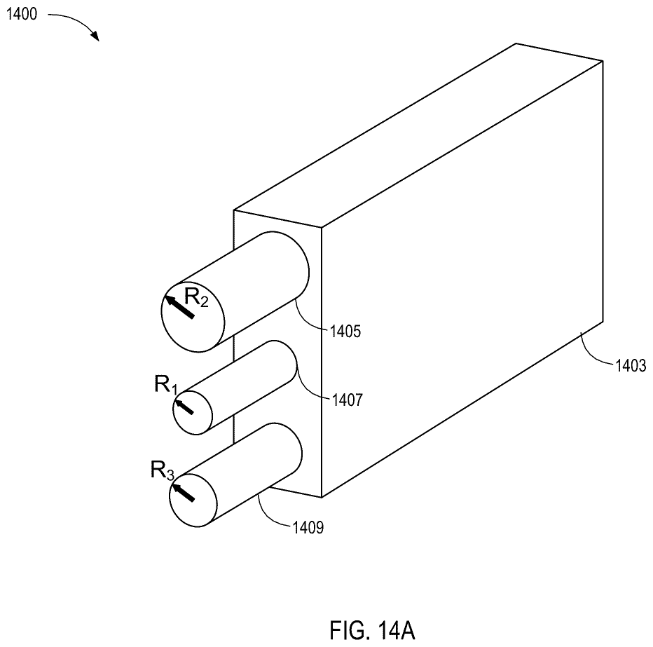

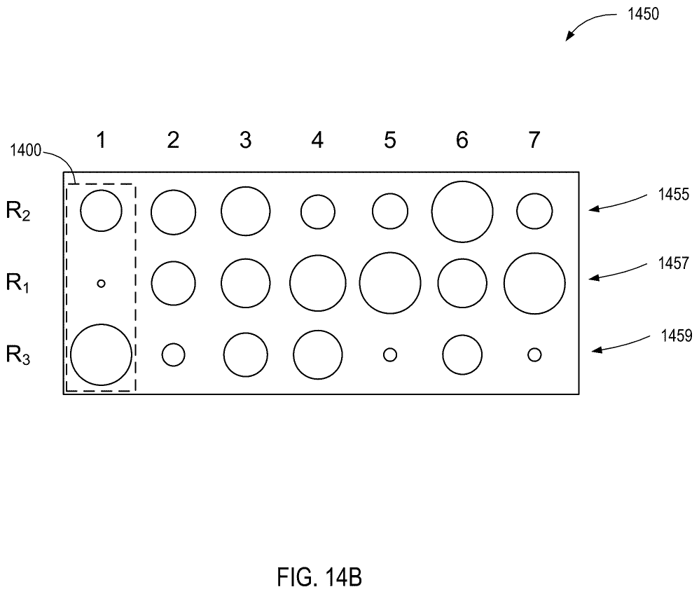

FIG. 14A illustrates an example of a unit-cell 1400 with three deflector elements 1405, 1407, and 1409 for an RGB display, according to one embodiment. Again, the specific diameters of each of the pillars 1405, 1407, and 1409 may be calculated via simulated phase delays of the specific frequencies used in the RGB display.

FIG. 14B illustrates an example multicell metalens 1450 with multiple unit cells 1400 for R, G, and B frequency responses, according to one embodiment. The unit cells 1400 of the metalens 1450 are formed via a repeating pattern of the unit-cells 1400 described in FIG. 14A, but with pillars 1405, 1407, and 1409 of varying diameters. Multiple multicell metalenses 1450 can be combined in a one-dimensional array or a two-dimensional array to form a larger one-dimensional metalens, a larger two-dimensional metalens, a metalens pixel with target dimensions, or a metalens subpixel with target dimensions. The illustrated multicell metalens 1450 includes rows of seven pillars having varying diameters, where each row may be responsive to deflect a particular frequency or frequency range of optical radiation.

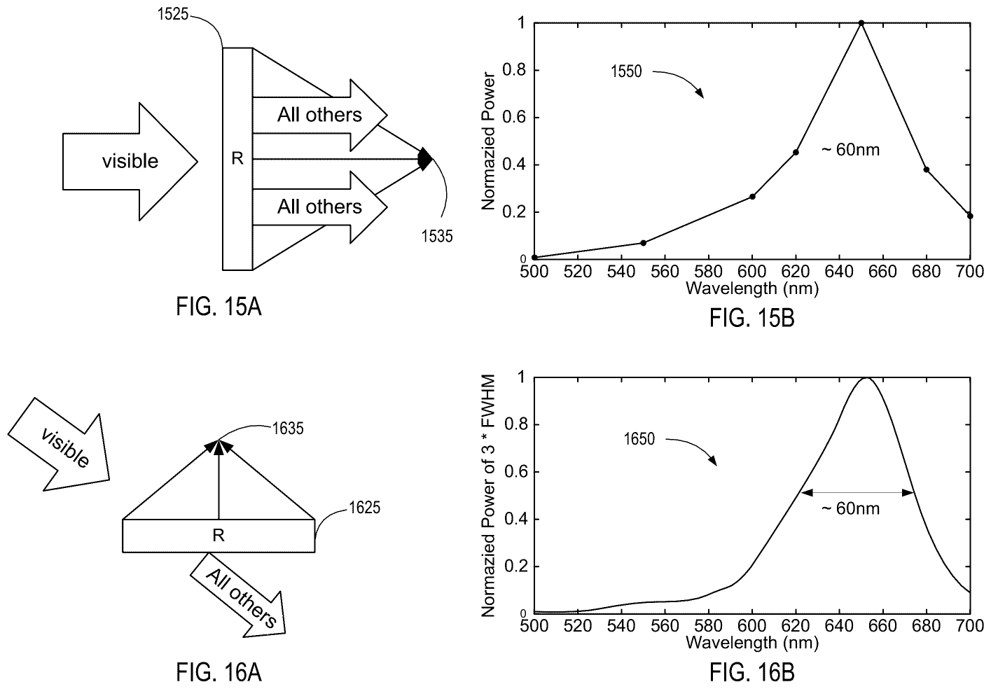

FIG. 15A illustrates an example of a transmissive metalens filter 1525 to focus a narrow band of optical radiation to a focal point 1535, according to one embodiment. Optical radiation outside of the narrow band passes through the transmissive metalens filter 1525 without being focused.

FIG. 15B illustrates a graph 1550 of the normalized power of the filtered and focused optical radiation with respect to wavelength, according to one embodiment. In the illustrated embodiment, a 60-nanometer band centered on approximately 650 nanometers is focused by the transmissive metalens filter 1525 of FIG. 5A. Other frequencies are not deflected to the focal point 1535 of FIG. 5A. Accordingly, the transmissive metalens filter 1525 can be described as a frequency-selective metalens or a narrowband filter and used for various applications to control deflection of a narrow band of optical radiation.

FIG. 16A illustrates a reflective metalens filter 1625 to reflectively focus a narrow band of optical radiation to a focal point 1635, according to one embodiment. Optical radiation outside of the narrow band passes through the reflective metalens filter 1625 without being reflected.

FIG. 16B illustrates a graph 1650 of the normalized power of the filtered and focused optical radiation with respect to wavelength, according to one embodiment. Again, approximately a 60-nanometer band of optical radiation centered on 650 nanometers is reflectively focused by the metalens filter 1625 of FIG. 6A. Other frequencies are not reflected. Instead, frequencies outside of the narrow band are passed through or marginally deflected to a location other than the focal point 1635 of FIG. 6B.

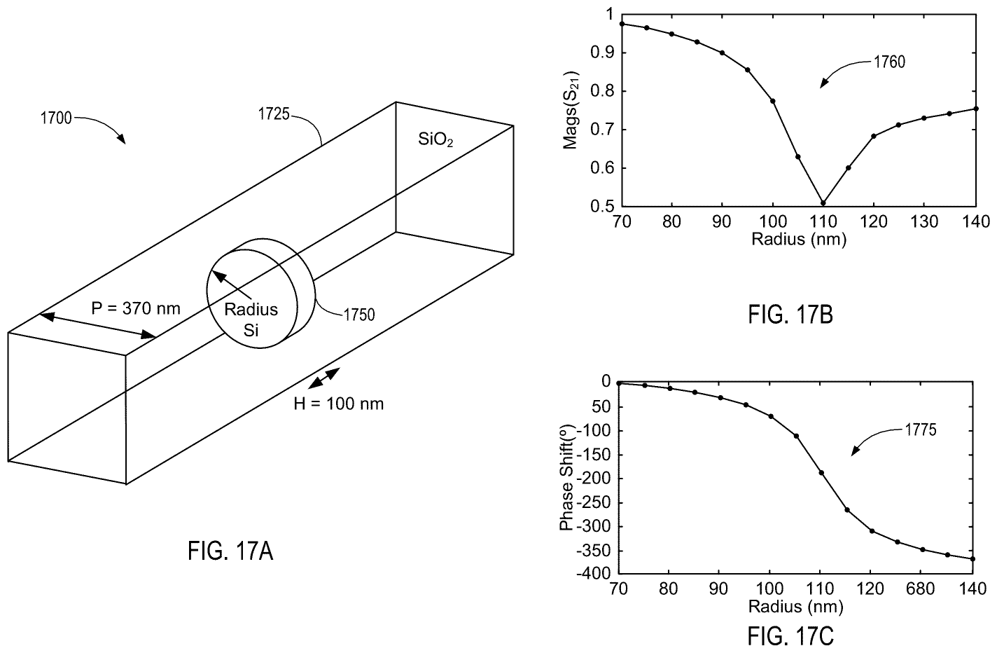

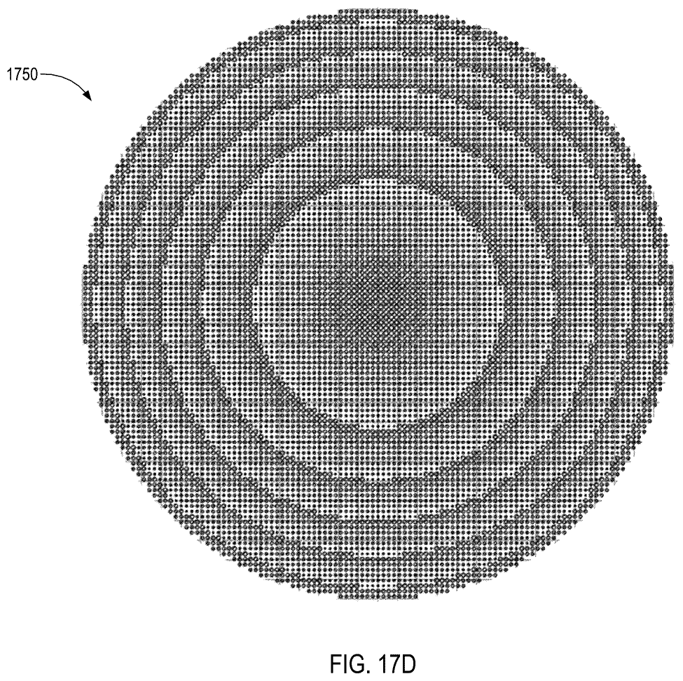

FIG. 17A illustrates a unit cell 1700 of an example narrowband frequency-selective filter, according to one embodiment. As illustrated, a disk-shaped array of deflector elements 1750 is positioned within a substrate 1725. The unit cell 1700 may be replicated as part of a one-dimensional or two-dimensional array with interelement spacing of approximately 370 nanometers, in some embodiments. The substrate 1725 may, for example, be formed of SiO₂. The disk of deflector elements 1750 may include deflector elements that have a height of approximately 100 nanometers, in some embodiments.

FIG. 17B illustrates a graph 1760 of the magnitude relative to radius selection of the array of passive deflector elements in the disk-shaped array of deflector elements 1750 of FIG. 17A, according to one embodiment.

FIG. 17C illustrates a graph 1775 of phase shift values relative to the various radius selections of the disk-shaped array of passive deflector elements 1750 of FIG. 17A, according to one embodiment. Similar to previously described embodiments, the radius of the disk-shaped array of passive deflector elements 1750 may be selected to achieve a target functionality of transmissivity and tunability.

FIG. 17D illustrates an example block diagram of the disk-shaped array of passive deflector elements 1750 for use in the unit cell 1700 of the example frequency-selective filter described in conjunction with FIGS. 17A-C, according to one embodiment.

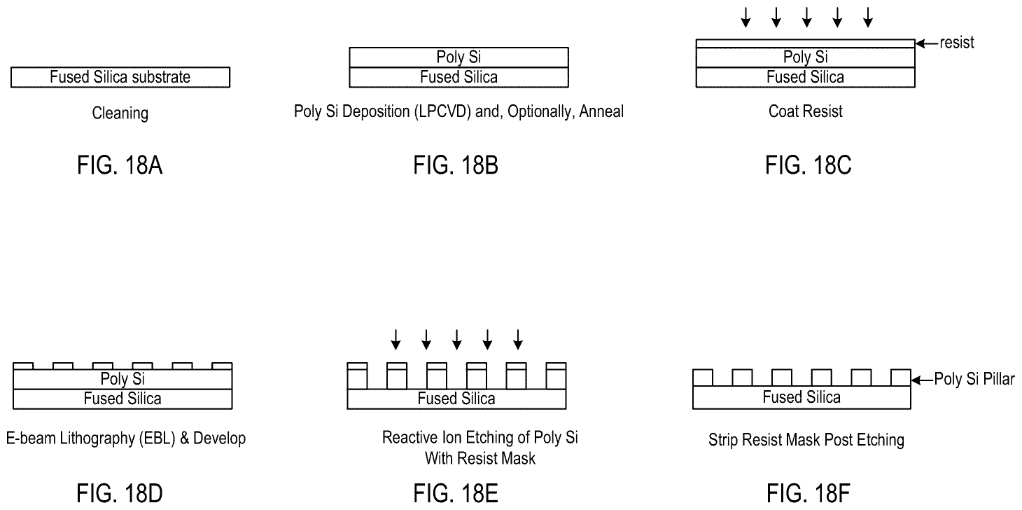

FIGS. 18A-18F illustrate an example process for fabricating a metalens with an array of passive deflector elements having varying diameters that extend from a substrate, according to one embodiment.

In FIG. 18A, a fused silica substrate is cleaned. In FIG. 18B, a poly-Si layer is deposited on the fused silica substrate. The poly-Si layer may, for example, be deposited using a low pressure chemical vapor deposition (LPCVD) process. In other embodiments, plasma enhanced chemical vapor deposition (PECVD), high-density plasma chemical vapor deposition (HDPCVD), and/or any of a wide variety of alternative chemical vapor deposition (CVD) processes may be utilized to deposit the poly-Si layer (or another suitable material) on the fused silica substrate (or another suitable substrate material).

As shown in FIG. 18C, a photoresist or other resist for lithography may be coated on the deposited poly-Si layer. In FIG. 18D, a lithography process, such as E-beam lithography (EBL) or another nanolithography approach, is used to define the pattern of deflector element diameters to be included in a metalens. As described herein, the pattern of deflector element diameters may be repeated one or more times and the pattern of deflector element diameters may be selected to provide a target deflection pattern for optical radiation within a target operational bandwidth.

As illustrated in FIG. 18E, reactive ion etching may be utilized to etch the poly-Si where the resist was not developed. In FIG. 18F, the resist may be removed to reveal the poly-Si pillars (or another shape of deflector element) extending from the fused silica substrate. While the side-view illustrations in FIGS. 18A-E show a one-dimensional row of pillars, it is appreciated that the same processes can be used to fabricate a two-dimensional array of pillars. The fabrication process may be used to fabricate each metalens pixel or metalens subpixel separately, after which the individual metalens pixels or metalens subpixels can be joined together. Alternatively, the fabrication process can be used to fabricate a complete two-dimensional array of metalens pixels or metalens subpixels as a single unit.

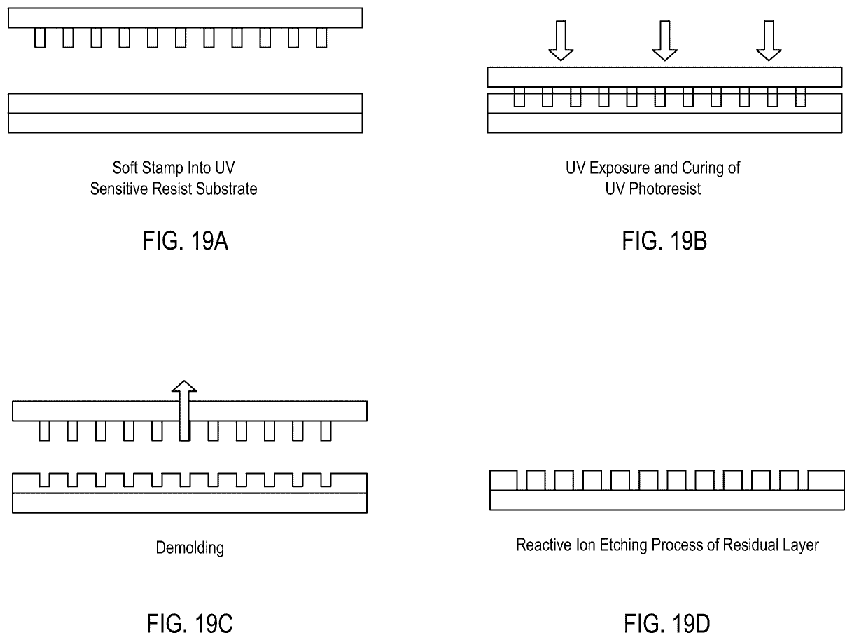

FIGS. 19A-19D illustrate another example process for fabricating a metalens with an array of passive deflector elements having varying diameters that extend from a substrate, according to one embodiment. In FIG. 19A, a mold may be used to soft-stamp a pattern of pillars having varying diameters into a resist that is, for example, sensitive to ultraviolet light. As shown in FIG. 19B, the resist may be cured or otherwise hardened. For example, an ultraviolet-sensitive photoresist may be exposed to ultraviolet light while the mold is soft-stamped therein.

As shown in FIG. 19C, the mold may be removed from the cured resist leaving pillar-shaped deflector elements. As shown in FIG. 19D, reactive ion etching of the residual layer can be used to generate a final array of pillars extending from the substrate. Again, while the illustrated examples include a one-dimensional row of a few pillars, it is appreciated that the described fabrication processes can be used to fabricate a two-dimensional array of pillars or deflector elements having an alternative shape. Additionally, the fabrication process can be used to fabricate a complete two-dimensional array of metalens pixels or metalens subpixels as a single unit, or as sub-unit panels that can be joined together or otherwise arranged to form a larger metalens.

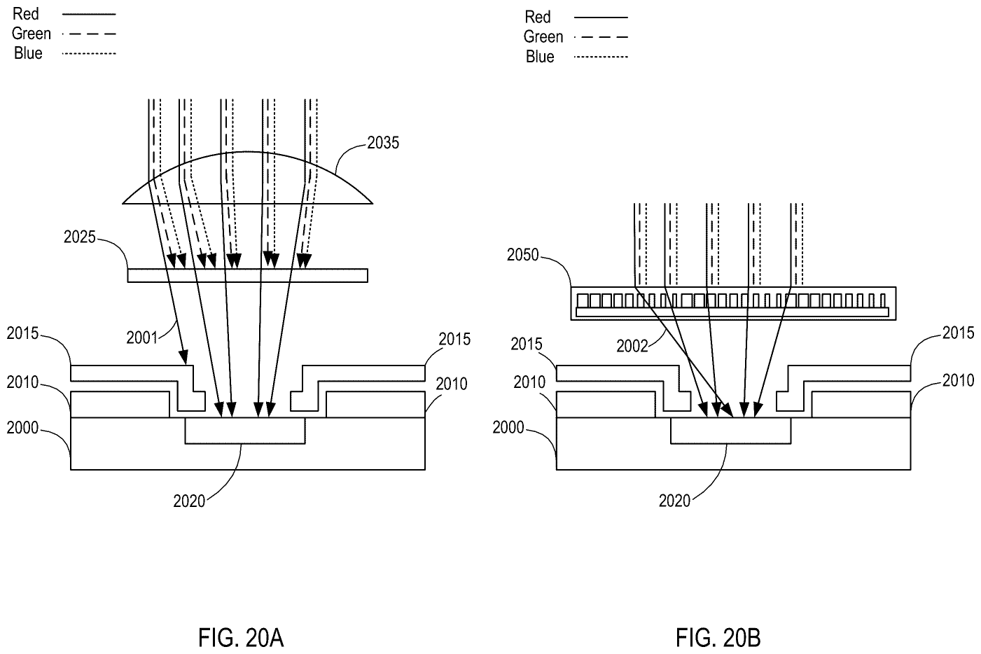

FIG. 20A illustrates a simplified diagram of a subpixel of a CMOS digital imaging sensor, according to one embodiment. In the illustrated embodiment, red (solid lines), green (dashed lines), and blue (dotted lines) optical radiation is received by a microlens 2035 that refracts the optical radiation toward a phototransistor 2020 for detection. The refracted optical radiation is filtered by a color filter 2025 based on the subpixel color. In this example, the subpixel is a red subpixel of the digital sensing array. Accordingly, the red optical radiation (solid lines) is passed through to the phototransistor 2020 for detection. The green and blue (dashed and dotted lines) optical radiation is filtered out by the color filter 2025. The example illustration of the subpixel includes a light shielding layer 2015 and electrodes 2010, as may be utilized in some embodiments of a CMOS digital sensing array. Notably, due to the limitations of the traditional optical elements, an optical ray path 2001 is refracted by the microlens 2035 toward the phototransistor 2020 but is blocked by the light shielding layer 2015.

FIG. 20B illustrates a subpixel of a digital imaging sensor using a metalens 2050 to filter and refract the optical radiation, according to one embodiment. As illustrated, the metalens 2050 may include a plurality of deflector elements extending from a substrate with a pattern of diameters, interelement spacings, and heights selected to perform the dual functions of refracting the red light toward the phototransistor 2020 and filtering out other wavelengths of optical radiation (e.g., the green and blue optical radiation). Usage of the metalens 2050 in place of the microlens 2035 and the color filter 2025 allows for a much thinner digital imaging sensor and potentially lower fabrication costs. Notably, the metalens 2050 may also allow for more control of the deflection (e.g., reflection and/or refraction) of the optical radiation. For instance, the optical ray path 2002 is refracted enough to be received by the phototransistor 2020 (as compared to optical ray path 2001 in FIG. 20A).

Various embodiments of the presently described metalenses (both refractive-type and reflective-type) may be used in combination with a wide variety of image sensing arrays, including RGB image sensing arrays using CCD and CMOS technologies. One or more metalenses may be used to provide the functionality of traditional microlens focusing, color filtering, infrared filtering, and/or other filtering and refracting functions. In some embodiments, the same metalens or an additional metalens may be used as the primary focusing lens for an imaging device and/or to supplement a traditional primary focusing lens of an imaging device.

This disclosure has been made with reference to various embodiments, including the best mode. However, those skilled in the art will recognize that changes and modifications may be made to the various embodiments without departing from the scope of the present disclosure. While the principles of this disclosure have been shown in various embodiments, many modifications of structure, arrangements, proportions, elements, materials, and components may be adapted for a specific environment and/or operating requirements without departing from the principles and scope of this disclosure. These and other changes or modifications are intended to be included within the scope of the present disclosure.

This disclosure is to be regarded in an illustrative rather than a restrictive sense, and all such modifications are intended to be included within the scope thereof. Likewise, benefits, other advantages, and solutions to problems have been described above with regard to various embodiments. However, benefits, advantages, solutions to problems, and any element(s) that may cause any benefit, advantage, or solution to occur or become more pronounced are not to be construed as a critical, required, or essential feature or element.

What is claimed is:

1. A frequency-selective optical filter, comprising:
a two-dimensional array of subwavelength unit cells, wherein each subwavelength unit cell comprises:
an optically transmissive medium; and
an array of passive deflector elements with varying diameters arranged within the optically transmissive medium,
wherein interelement on-center spacings of the passive deflector elements are selected to:
reflect optical radiation within a target bandwidth to a focal point, and
deflect or pass optical radiation at frequencies outside of the target bandwidth to locations other than the focal point,
wherein the array of passive deflector elements is configured for a dual-frequency response with the interelement on-center spacings of a first set of the passive deflector elements selected as a function of a first operational wavelength and the interelement on-center spacings of a second set of the passive deflector elements selected as a function of a second operational wavelength of the optical metalens.

2. The filter of claim 1, wherein each of the deflector elements comprises a cylinder having a diameter (D), a height (H), and an on-center nearest neighbor interelement spacing (P), wherein the diameter (D) of each deflector element varies based on the relative location of the deflector element in the repeating pattern.

3. The filter of claim 1, wherein the passive deflector elements are polarization-independent.

4. A frequency-selective optical filter, comprising:
a two-dimensional array of subwavelength unit cells, wherein each subwavelength unit cell comprises:
an optically transmissive medium; and
an array of passive deflector elements with varying diameters arranged within the optically transmissive medium,
wherein interelement on-center spacings of the passive deflector elements are selected to:
reflect optical radiation within a target bandwidth to a focal point, and
deflect or pass optical radiation at frequencies outside of the target bandwidth to locations other than the focal point,
wherein the array of passive deflector elements of each subwavelength unit cell is configured for a multi-frequency response with the interelement on-center spacings of a first set of the passive deflector elements selected as a function of a first operational wavelength, the interelement on-center spacings of a second set of the passive deflector elements selected as a function of a second operational wavelength of the optical metalens, and the interelement on-center spacings of a third set of the passive deflector elements selected as a function of a third operational wavelength of the optical metalens.

5. The filter of claim 4, wherein each of the deflector elements comprises a cylinder having a diameter (D), a height (H), and an on-center nearest neighbor interelement spacing (P), wherein the diameter (D) of each deflector element varies based on the relative location of the deflector element in the repeating pattern.

6. The filter of claim 4, wherein the passive deflector elements are polarization-independent.

7. A frequency-selective optical filter, comprising:
a two-dimensional array of subwavelength unit cells, wherein each subwavelength unit cell comprises:
an optically transmissive medium; and
an array of passive deflector elements with varying diameters arranged within the optically transmissive medium,
wherein interelement on-center spacings of the passive deflector elements are selected to:
reflect optical radiation within a target bandwidth to a focal point, and
deflect or pass optical radiation at frequencies outside of the target bandwidth to locations other than the focal point.

8. The filter of claim 7, wherein each of the deflector elements comprises a cylinder having a diameter (D), a height (H), and an on-center nearest neighbor interelement spacing (P), wherein the diameter (D) of each deflector element varies based on the relative location of the deflector element in the repeating pattern.

9. The filter of claim 7, wherein the passive deflector elements are polarization-independent.

10. The filter of claim 7, wherein the array of passive deflector elements of each subwavelength unit cell is configured for a multi-frequency response with the interelement on-center spacings of a first set of the passive deflector elements selected as a function of a first operational wavelength, the interelement on-center spacings of a second set of the passive deflector elements selected as a function of a second operational wavelength of the optical metalens, and the interelement on-center spacings of a third set of the passive deflector elements selected as a function of a third operational wavelength of the optical metalens.

11. The filter of claim 7, wherein the array of passive deflector elements is configured for a dual-frequency response with the interelement on-center spacings of a first set of the passive deflector elements selected as a function of a first operational wavelength and the interelement on-center spacings of a second set of the passive deflector elements selected as a function of a second operational wavelength of the optical metalens.
